(19) United States
(12) Patent Application Publication
(10) Pub. No.: US 2026/0363406 A1
(43) Pub. Date: Nov. 19, 2026

(54) EARPIECE, EARPIECE HOLDER, SYSTEM, AND METHOD OF USE

(71) Applicant: bagelab LLC, Santa Fe, NM (US)

(72) Inventor: Noah Sapir, Albuquerque, CA (US)

(73) Assignee: bagelab LLC, Santa Fe, CA (US)

(21) Appl. No.: 19/210,945

(22) Filed: May 16, 2025

(51) Int. Cl. A45C 11/00; A45C 13/10; H04R 1/1025; H05K 5/02

(52) U.S. Cl. CPC A45C 11/001; A45C 13/1069; H05K 5/0247; H04R 1/1025

(57) ABSTRACT

Aspects include a system, an earpiece, an earpiece holder, and a method of using such. A system may comprise an earpiece, an earpiece holder, and at least one releasable fastener. The earpiece holder comprises a housing having a fulcrum engageable with a pivot point of the earpiece such that the earpiece can pivot about the fulcrum between a first position and a second position. The earpiece holder may further comprise a first earpiece body support configured to engage the earpiece body when the earpiece body is in the first position. The at least one releasable fastener may be configured for releasably attaching the first portion of the earpiece body to the first earpiece body support when the earpiece body is in the first position.

### TECHNICAL FIELD

Embodiments relate to earpieces, earpiece holders, systems comprising such, and methods of using such.

### SUMMARY OF THE INVENTION

Aspects of the present technology may include but are not limited to a system, an earpiece holder, an earpiece, a method of using the system, a method of using the earpiece, or a method of using the earpiece holder.

A first aspect of the present technology provides a system. The system comprises an earpiece and an earpiece holder. The system may include a first releasable fastener. The earpiece may comprise an audio transmitter and an earpiece body. The earpiece holder may comprise a housing. The housing may have a first earpiece body support. The housing may have a fulcrum. The earpiece body may comprise a first portion, a second portion, and a third portion, wherein the fulcrum is engageable with the third portion of the earpiece body such that the earpiece body can pivot about the fulcrum from a first position to a second position and from the second position to the first position. The first earpiece body support may be configured to engage the earpiece body when the earpiece body is in the first position. The first earpiece body support may be disposed a distance from the fulcrum. The first earpiece body support may be configured to engage the first portion of the earpiece body. The first releasable fastener may be configured for releasably fixing the earpiece to the earpiece holder in the first position. The first releasable fastener may be configured for releasably attaching the first portion of the earpiece body to the first earpiece body support when the earpiece body is in the first position.

The first releasable fastener may comprise a coupler fixed to the earpiece and a coupler fixed to the earpiece holder, wherein the couplers interact with each other to form the first releasable fastener.

The first releasable fastener may comprise at least one magnet. The at least one magnet may comprise a magnet disposed about the earpiece and/or a magnet disposed about the earpiece holder. The at least one magnet may be disposed about an interface of the first earpiece body support and the first portion.

The third portion may be between the first portion and the second portion. The earpiece holder may further comprise a second earpiece body support. The second earpiece body support may be configured to engage the earpiece body when the earpiece body is in the second position. The second earpiece body support may be disposed a distance from the fulcrum. The fulcrum may be between the first earpiece body support and the second earpiece body support.

The system may further comprise a second releasable fastener. The second releasable fastener may be configured for releasably fixing the earpiece to the earpiece holder in the second position. The second releasable fastener may be configured for releasably attaching the second portion of the earpiece body to the second earpiece body support when the earpiece body is in the second position. The second releasable fastener may comprise at least one magnet. The at least one magnet of the second releasable fastener may comprise a magnet disposed about the earpiece and/or a magnet disposed about the earpiece holder. The at least one magnet of the second releasable fastener may be disposed about an interface of the second earpiece body support and the second portion of the earpiece body.

The second releasable fastener may comprise a coupler fixed to the earpiece and a coupler fixed to the earpiece holder, wherein the couplers interact with each other to form the second releasable fastener.

The first portion of the earpiece body may have an ear interface. The earpiece holder may further comprise a cavity for receiving the ear interface (‘ear interface cavity’) at least when the earpiece body is in the first position.

The earpiece holder may further comprise a cavity in which the fulcrum is disposed (‘fulcrum cavity’).

The fulcrum cavity may have a cavity wall, wherein the ear interface cavity is recessed in the cavity wall of the fulcrum cavity.

The earpiece holder may comprise a magnet comprising a first portion and a second portion, wherein the first portion of the magnet comprises the fulcrum and the second portion of the magnet comprises a coupler of the first releasable fastener.

The fulcrum cavity may be configured such that when the earpiece body is in the second position, the second portion is inside the fulcrum cavity and another portion of the earpiece body protrudes from the fulcrum cavity. The fulcrum cavity may be further configured such that when the earpiece body is in the first position, said another portion of the earpiece body is in the fulcrum cavity, e.g., such that the another portion does not protrude from the fulcrum cavity. Said another portion of the earpiece body may comprise a lifting edge. The another portion of the earpiece body may be at least part of the first portion and/or may be a distal end of the earpiece body. The fulcrum cavity may be further configured such that when the earpiece body is in the first position, the second portion is in the fulcrum cavity, e.g., such that second portion does not protrude from the fulcrum cavity.

The system may further comprise a detection circuit configured to detect a change in position of the earpiece relative to the earpiece holder. The detection circuit may be further configured to execute a function of the system responsive to said detection of the change in position. The detection circuit may have a proximity sensor configured to detect said change in position based on proximity of the earpiece relative to the earpiece holder. The change in position may be a change from the first position to the second position or from the second position to the first position.

The earpiece holder may have a power source, such as a battery. The earpiece may have a battery. The system may be configured to charge the battery of the earpiece from the power source of the earpiece holder.

The earpiece may have a first set of conductors operably connected to the battery of the earpiece, wherein the earpiece holder has a second set of conductors operably connected to the power source of the earpiece holder, and wherein the first set of conductors and the second set of conductors are disposed in respective locations about the earpiece and the earpiece holder, respectively, such that the first set of conductors and the second set of conductors are electrically connected to each other when the earpiece body is in the first position. The second set of conductors may be disposed about the first earpiece body support. The first set of conductors may be disposed about the first portion of the earpiece body.

The earpiece may have a receiver coil operably connected to the battery of the earpiece. The earpiece holder may have a sender coil operably connected to the power source of the earpiece holder. The receiver coil and the sender coil may be disposed in respective locations about the earpiece and the earpiece holder, respectively, such that the receiver coil and the sender coil are inductively coupled to each other when the earpiece body is in the first position. The sender coil may be disposed about the first earpiece body support. The receiver coil may be disposed about the first portion of the earpiece body.

The earpiece holder may have a switch that is activatable upon the earpiece body being pivoted to the second position. The switch may be disposed about the second earpiece body support. The switch may be a mechanical switch.

The earpiece holder may have a base on an opposing side of the earpiece holder, relative to the fulcrum. The base may have: at least one foot, and at least one balancing portion on which the earpiece holder can balance when the earpiece holder may be placed on a horizontal surface. The at least one balancing portion and the at least one foot may each be disposed about the earpiece holder such that, when the earpiece holder is balanced on the horizontal surface by the at least one balancing portion, the at least one balancing portion is lower than the at least one foot and when a downward force is applied laterally of the at least one balancing portion to rock the earpiece holder about the at least one balancing portion, the at least one foot is rocked in a downward direction to engage the horizontal surface. The at least one foot may be configured to prevent further rocking in the downward direction when engaged with the horizontal surface. The base may have a convex arc. The at least one balancing portion may be a portion of the convex arc. The at least one foot may protrude from the convex arc.

The earpiece holder may have a central portion, a first end, and a second end, wherein the central portion is between the first end and the second end. The earpiece holder may taper from the central portion to the first end in one or both of lateral thickness and longitudinal thickness. The earpiece holder may taper from the central portion to the second end in one or both of lateral thickness and longitudinal thickness. The taper from the central portion to the first end in one or both of lateral thickness and longitudinal thickness may be more gradual than the taper from the central portion to the second end in one or both of lateral thickness and longitudinal thickness. The taper from the central portion to the first end in lateral thickness may be longitudinally symmetrical. The taper from the central portion to the second end in lateral thickness may be longitudinally symmetrical. The taper from the central portion to the first end in longitudinal thickness may be laterally symmetrical. The taper from the central portion to the second end in longitudinal thickness may be laterally symmetrical. Any one or any combination of the tapers may be an arcuate taper. The earpiece holder may have an almond shape.

The earpiece may have a central portion, a first end, and a second end, wherein the central portion is between the first end and the second end. The earpiece may taper from the central portion to the first end in one or both of lateral thickness and longitudinal thickness. The earpiece may taper from the central portion to the second end in one or both of lateral thickness and longitudinal thickness. The taper from the central portion to the first end in one or both of lateral thickness and longitudinal thickness may be more gradual than the taper from the central portion to the second end in one or both of lateral thickness and longitudinal thickness. The taper from the central portion to the first end in lateral thickness may be longitudinally symmetrical. The taper from the central portion to the second end in lateral thickness may be longitudinally symmetrical. The taper from the central portion to the first end in longitudinal thickness may be laterally symmetrical. The taper from the central portion to the second end in longitudinal thickness may be laterally symmetrical. Any one or any combination of the tapers may be an arcuate taper. The earpiece may have an almond shape.

The earpiece body may comprise a lifting edge engageable by a user's finger when the earpiece body is in the first position and/or the second position. The lifting edge may be disposed about the earpiece body at a location such that lifting of the earpiece body by the lifting edge causes the earpiece body to pivot about the fulcrum from the first position to the second position and/or from the second position to another position. The lifting edge may be part of the second portion of the earpiece body. The system may be configured such that the earpiece body and the fulcrum together form a second class lever when the user lifts the earpiece body by the lifting edge. The first portion may be between the second portion and third portion. The third portion may be positioned about an end of the earpiece body. The second portion of the earpiece body may be positioned relative to the third portion of the earpiece body such that, when the earpiece body is in the second position, the third portion of the earpiece body is supported by the earpiece holder, and the second portion of the earpiece body is raised from the cavity, relative to the position of the second portion of the earpiece body when the earpiece body is in the first position. The earpiece holder may comprise a second earpiece body support for said supporting the third portion of the earpiece body when the earpiece body is in the second position. The second earpiece body support may be positioned about the earpiece holder such that the second earpiece body support is engaged with the third portion of the earpiece body at least when the earpiece body is in the second position. The second earpiece body support may be positioned about the earpiece holder such that the second earpiece body support is engaged with the third portion of the earpiece body when the earpiece body is in the first position. The second earpiece body support may be positioned about the earpiece holder such that the second earpiece body support is engaged with the third portion of the earpiece body when the earpiece body is in the first position and when the earpiece body is in the second position. The second earpiece body support may comprise the fulcrum. The third portion of the earpiece body support may comprise a protrusion, wherein fulcrum comprises a concave surface engageable by the protrusion for pivoting of the earpiece body about the concave surface by the protrusion. The protrusion engageable by the fulcrum may be an end of the earpiece body, such as a distal end. The first releasable fastener may comprise at least one magnet.

Any one or any combination of the aforementioned features may be combined with a system of the present technology, except where the configuration of said features expressly conflict with each other. Additionally, the present technology contemplates the provision of the earpiece or earpiece holder independently of the system. As such, in some aspects, the present technology provides an earpiece holder and in other aspects, the present technology provides an earpiece, e.g. as described below.

A second aspect of the present technology provides an earpiece holder.

The earpiece holder may be an earpiece holder for storing an earpiece having a first portion, a second portion, and a third portion. The earpiece holder may comprise a housing. The earpiece holder may further comprise a coupler of a first releasable fastener. The housing may comprise a fulcrum. The housing may comprise a first earpiece body support. The fulcrum may be engageable with the third portion such that the earpiece body can pivot about the fulcrum from a first position to a second position and from the second position to the first position. The first earpiece body support may be disposed a distance from the fulcrum and configured to engage the earpiece body when the earpiece body is in the first position. The first releasable fastener may be configured for releasably attaching the first portion of the earpiece body to the first earpiece body support when the earpiece body is in the first position.

The earpiece holder may comprise a coupler of a second releasable fastener configured for releasably attaching the second portion of the earpiece body to a second earpiece body support of the earpiece holder when the earpiece body is in the second position. The coupler of a second releasable fastener may comprise a magnet disposed about the second earpiece body support of the earpiece holder.

The coupler of a second releasable fastener of the earpiece holder of the second aspect may have any of the features or configurations described with respect to the second releasable fastener of the system of the first aspect.

The coupler of a first releasable fastener of the earpiece holder of the second aspect may have any of the features or configurations described with respect to the first releasable fastener of the system of the first aspect.

The earpiece holder of the second aspect may have any of the features or configurations described with respect to the earpiece holder of the system of the first aspect.

A third aspect of the present technology provides an earpiece. The earpiece may be configured for storage by an earpiece holder having a fulcrum and a first earpiece body support, wherein the earpiece comprises an audio transmitter and an earpiece body. The earpiece may comprise a coupler of a first releasable fastener. The earpiece body may comprise a first portion, a second portion, and a third portion, the third portion being configured to engage the fulcrum such that the earpiece body can pivot about the fulcrum from a first position to a second position and from the second position to the first position. The first releasable fastener may be configured for releasably attaching the first portion of the earpiece body to a first earpiece body support of the earpiece holder when the earpiece body is in the first position.

The earpiece may comprise a coupler of a second releasable fastener configured for releasably attaching the second portion of the earpiece body to a second earpiece body support of the earpiece holder when the earpiece body is in the second position. The coupler of a second releasable fastener may comprise a magnet disposed about the second portion of the earpiece body.

The coupler of a first releasable fastener of the earpiece may comprise a magnet. The magnet may have a flat surface. The magnet or a flat surface thereof may be disposed across the first portion and the third portion.

The coupler of a first releasable fastener of the earpiece of the third aspect may have any of the features or configurations described with respect to the first releasable fastener of the system of the first aspect.

The coupler of a second releasable fastener of the earpiece of the third aspect may have any of the features or configurations described with respect to the second releasable fastener of the system of the first aspect.

The earpiece of the third aspect may have any of the features or configurations described with respect to the earpiece of the system of the first aspect.

A fourth aspect of the present technology provides a method of using the system of the first aspect. The method may comprise any one or any combination of the following steps: providing the system; pivoting the third portion of the earpiece body about the fulcrum to move the earpiece body from the second position to the first position; attaching the first portion of the earpiece body to the first earpiece body support when the earpiece body is in the first position; detaching the first portion of the earpiece from the first earpiece body support; and pivoting the third portion of the earpiece body about the fulcrum to move the earpiece body from the first position to the second position.

The method may further comprise attaching the second portion of the earpiece body to a second earpiece body support of the earpiece holder when the earpiece body is in the second position.

The method may further comprise causing a controller of the earpiece holder to perform control of at least one electronic component of the earpiece holder responsive to said pivoting the third portion of the earpiece body about the fulcrum to move the earpiece body from the second position to the first position or said pivoting the third portion of the earpiece body about the fulcrum to move the earpiece body from the first position to the second position.

A fifth aspect of the present technology provides a method of using the earpiece holder of the second aspect. The method may comprise any one or any combination of the following steps: providing the earpiece holder and an earpiece having an earpiece body comprising a first portion, a second portion and a third portion; pivoting the third portion of the earpiece body about the fulcrum to move the earpiece body from the second position to the first position; attaching the first portion of the earpiece body to the first earpiece body support when the earpiece body is in the first position; detaching the first portion of the earpiece from the first earpiece body support; and pivoting the third portion of the earpiece body about the fulcrum to move the earpiece body from the first position to the second position.

The method may further comprise attaching the second portion of the earpiece body to a second earpiece body support of the earpiece holder when the earpiece body is in the second position.

The method may further comprise causing a controller of the earpiece holder to perform control of at least one electronic component of the earpiece holder responsive to said pivoting the third portion of the earpiece body about the fulcrum to move the earpiece body from the second position to the first position or said pivoting the third portion of the earpiece body about the fulcrum to move the earpiece body from the first position to the second position.

A sixth aspect of the present technology provides a method of using the earpiece of the third aspect. The method may comprise any one or any combination of the following steps: providing the earpiece and an earpiece holder having a fulcrum; pivoting the third portion of the earpiece body about the fulcrum to move the earpiece body from the second position to the first position; attaching the first portion of the earpiece body to a first earpiece body support of the earpiece holder when the earpiece body is in the first position; detaching the first portion of the earpiece from the first earpiece body support; and pivoting the third portion of the earpiece body about the fulcrum to move the earpiece body from the first position to the second position.

The method may further comprise attaching the second portion of the earpiece body to a second earpiece body support of the earpiece holder when the earpiece body is in the second position.

A seventh aspect of the present technology provides a method comprising providing a system comprising an earpiece and an earpiece holder, wherein the earpiece comprises an audio transmitter and an earpiece body, wherein the earpiece body comprises a first portion, a second portion, and a third portion, wherein the earpiece holder comprises a housing having a fulcrum, and wherein the fulcrum is engageable with the third portion of the earpiece body such that the earpiece body can pivot about the fulcrum from a first position to a second position and from the second position to the first position; pivoting the third portion of the earpiece body about the fulcrum to move the earpiece body from the second position to the first position; and pivoting the third portion of the earpiece body about the fulcrum to move the earpiece body from the first position to the second position.

The method may further comprise retaining the earpiece body in the first position for a period of time. The step of retaining the earpiece body in the first position for a period of time may comprise releasably attaching the earpiece body to the earpiece holder by a first releasable fastener. The first releasable fastener may comprise a magnet.

The method may further comprise retaining the earpiece body in the second position for a period of time. The step of retaining the earpiece body in the second position for a period of time may comprise releasably attaching the earpiece body to the earpiece holder by a second releasable fastener. The second releasable fastener may comprise a magnet.

The earpiece holder may have any one or any combination of the features described with respect to any other aspect of the present technology described herein.

The earpiece may have any one or any combination of the features described with respect to any other aspect of the present technology described herein.

### BRIEF DESCRIPTION OF THE DRAWINGS

FIG. 1A depicts a top perspective view of a system of the present technology according to some embodiments. The system is shown when the earpiece is in a first position.

FIG. 1B depicts a top perspective view of the system of FIG. 1A when the earpiece is in a second position.

FIG. 1C depicts a section view of the system of FIG. 1A when the earpiece is in the first position.

FIG. 1D depicts a section view of the system of FIG. 1A when the earpiece is between the first position and the second position.

FIG. 1E depicts a section view of the system of FIG. 1A when the earpiece is in the second position.

FIG. 1F depicts a section view of the system of FIG. 1A when the earpiece is removed from the earpiece holder.

FIG. 1G depicts a perspective view of the system of FIG. 1A when the earpiece is removed from the earpiece holder.

FIG. 1H depicts a top perspective view of a system of the present technology according to some embodiments. The system is shown when the earpiece is in a first position.

FIG. 1I depicts a perspective view of the system of FIG. 1H when the earpiece is in a second position.

FIG. 1J depicts a section view of the system of FIG. 1H when the earpiece is in the first position.

FIG. 1K depicts a section view of the system of FIG. 1H when the earpiece is between the first position and the second position.

FIG. 1L depicts a section view of the system of FIG. 1H when the earpiece is in the second position.

FIG. 1M depicts a section view of the system of FIG. 1H when the earpiece is removed from the earpiece holder.

FIG. 1N depicts a perspective view of the system of FIG. 1H when the earpiece is removed from the earpiece holder.

FIG. 2 depicts a top perspective view of a system of the present technology according to some embodiments. The system is shown when the earpiece is in a first position.

FIG. 3 depicts a top perspective view of the system of FIG. 2 when the earpiece is in a second position.

FIG. 4 depicts a bottom perspective view of the earpiece holder of the system of FIG. 2.

FIG. 5 depicts a top view of the system of FIG. 2.

FIG. 6 depicts the system of FIG. 2, shown with the earpiece removed from the earpiece holder. The top side of the earpiece holder is shown. The bottom side of the earpiece is shown.

FIG. 7 depicts a bottom view of the earpiece holder of the system of FIG. 2, shown with the bottom portion of its housing removed.

FIG. 8 depicts a side elevational sectional view system of FIG. 2, shown with the earpiece removed from the earpiece holder.

FIG. 9 depicts a side elevational section view of the system of FIG. 2, shown with the earpiece in the first position.

FIG. 10 depicts a side elevational section view of the system of FIG. 2, shown with the earpiece between the first position and the second position.

FIG. 11 depicts a side elevational section view of the system of FIG. 2, shown with the earpiece in the second position.

FIG. 12 depicts a bottom perspective exploded view of the earpiece holder of the system of FIG. 2, shown with the bottom portion of its housing removed.

FIG. 13 depicts a side elevational view of the system FIG. 2, balancing on a horizontal surface, and shown with the earpiece in the first position.

FIG. 14 depicts a side elevational view of the system of FIG. 2, shown with the earpiece in the first position, and sitting on the horizontal surface, with relatively weak pressure being applied to the right end of the earpiece to rock the right end of the earpiece holder down towards the horizontal surface.

FIG. 15 depicts a side elevational view of the system of FIG. 2, sitting on the horizontal surface, shown with the earpiece having been pivoted to the second position and the right side of the earpiece holder having been rocked down towards the horizontal surface from a relatively strong pressure being applied to the right end of the earpiece.

FIG. 16 depicts a system of the present technology according to some embodiments.

FIG. 17A depicts a perspective view of a system of the present technology according to some embodiments. The system is shown when the earpiece is in a first position.

FIG. 17B depicts a section view of the system of FIG. 17A when the earpiece is in the first position.

FIG. 17C depicts a section view of the system of FIG. 17A when the earpiece is in a second position.

FIG. 18 depicts diagrams of the layout of electronic components of a system of the present technology.

### DETAILED DESCRIPTION OF THE PREFERRED EMBODIMENTS

In the following description, for purposes of explanation and not limitation, specific details are set forth, such as particular embodiments, procedures, techniques, etc. in order to provide a thorough understanding of the present invention. However, it will be apparent to one skilled in the art that the present invention may be practiced in other embodiments that depart from these specific details.

Certain terminology is used in the following description for convenience only and is not limiting. The words “right,” “left,” “top,” and “bottom” designate directions in the drawings to which reference is made. The words “a” and “one,” as used in the claims and in the corresponding portions of the specification, are defined as including one or more of the referenced items unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof. “Exemplary” (or “e.g.” or “for example” or “[numbered component of a figure]”) means an example contemplated by the present technology. “May” means “may, for example”. References to such examples are not intended to limit the entire scope of the present technology thereto. Accordingly, the present technology also contemplates alternative embodiments which are not limited to such examples.

For the purpose of illustrating the present technology, certain embodiments are the drawings. It is understood, however, that the invention is not limited to the precise arrangements and instrumentalities shown.

### Overview

Technical features described in this application can be used to construct various embodiments according to the present technology of earpiece technology. In a first aspect of the present technology, a system comprises an earpiece and an earpiece holder. In a second aspect of the present technology, an earpiece holder comprises a fulcrum for pivoting an earpiece there on. In a third aspect of the present technology, an earpiece comprises a pivot point for pivoting about a fulcrum of an earpiece holder. In a fourth aspect of the present technology, a method comprises pivoting an earpiece about a fulcrum of an earpiece holder.

In one approach, the system of the present technology comprises an earpiece and an earpiece holder. The earpiece holder may comprise a fulcrum and the earpiece may comprise a pivot point for pivoting about the fulcrum.

By providing a system in which an earpiece holder comprises a fulcrum and the earpiece comprises a pivot point, according to some embodiments, the earpiece can be pivoted about the fulcrum between a first position and a second position.

The system may comprise at least one releasable fastener configured for releasably fixing the earpiece in the first position and/or the second position.

By providing a system comprising at least one releasable fastener, according to some embodiments, the earpiece can be securely stabilized in the earpiece holder in the first position and/or second position.

The earpiece holder may comprise a cavity. The cavity may be configured such that a portion of the earpiece, such a lifting edge, is in the cavity when the earpiece is in the first position and the portion of the earpiece protrudes from the cavity when the earpiece is in the second position.

By providing a system in which the cavity is configured such that a portion of the earpiece, such as a lifting edge, is in the cavity when the earpiece is in the first position and the portion of the earpiece protrudes from the cavity when the earpiece is in the second position, according to some embodiments, the earpiece can be securely stowed in the first position and prevented from accidental deployment, and the earpiece is readied for easy deployment when the earpiece is in the second position.

The system may be configured to detect the position of the earpiece relative to the earpiece holder.

By configuring the system to detect the position of the earpiece relative to the earpiece holder, according to some embodiments, electronic functions of the system may be controlled responsive to a change in the position.

The earpiece holder may comprise at least one foot and a balancing portion on which the earpiece holder can balance when the earpiece holder is placed on a horizontal surface.

By providing a system comprising at least one foot and a balancing portion on which the earpiece holder can balance, according to some embodiments, a user is provided with an enjoyable fidget which spins and rocks.

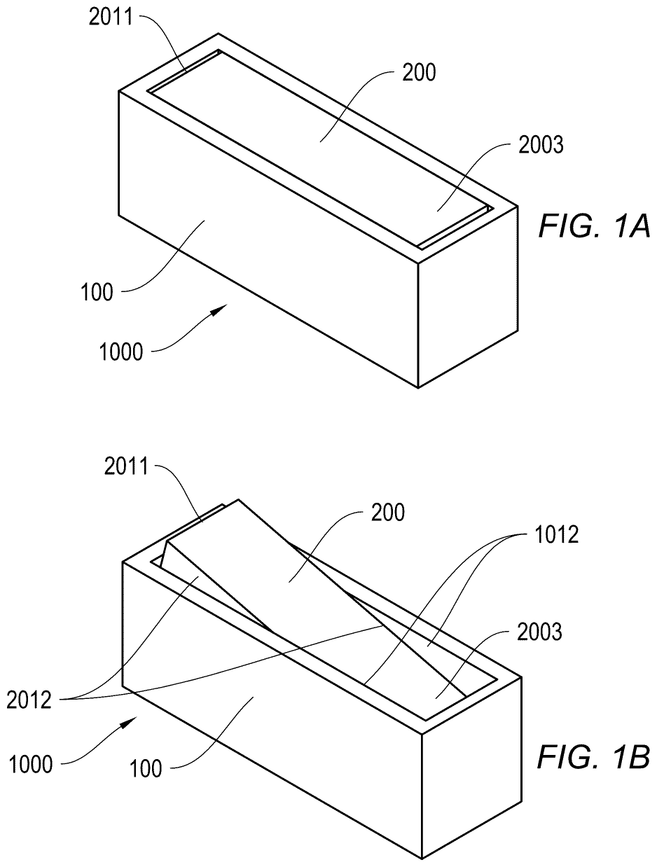

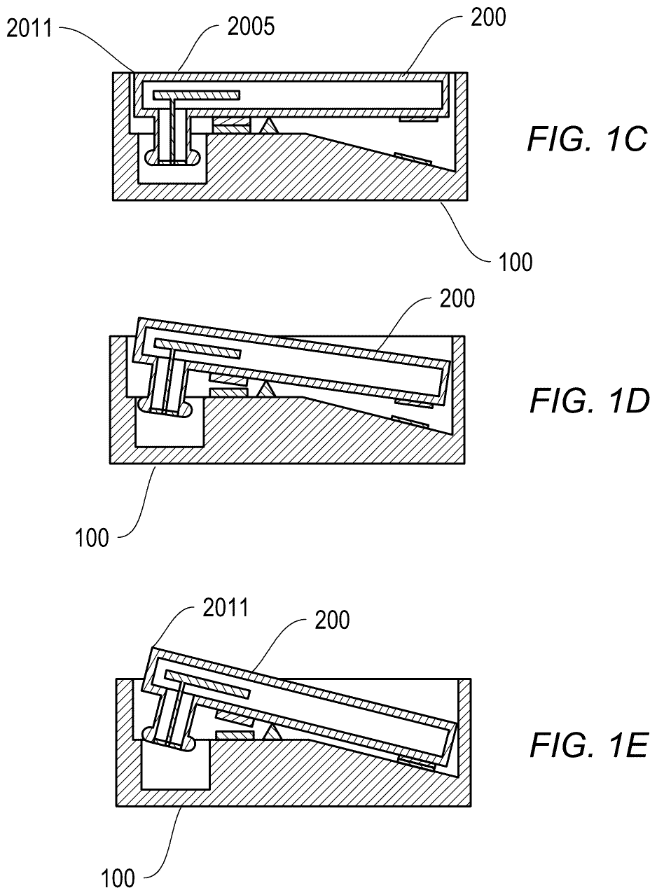

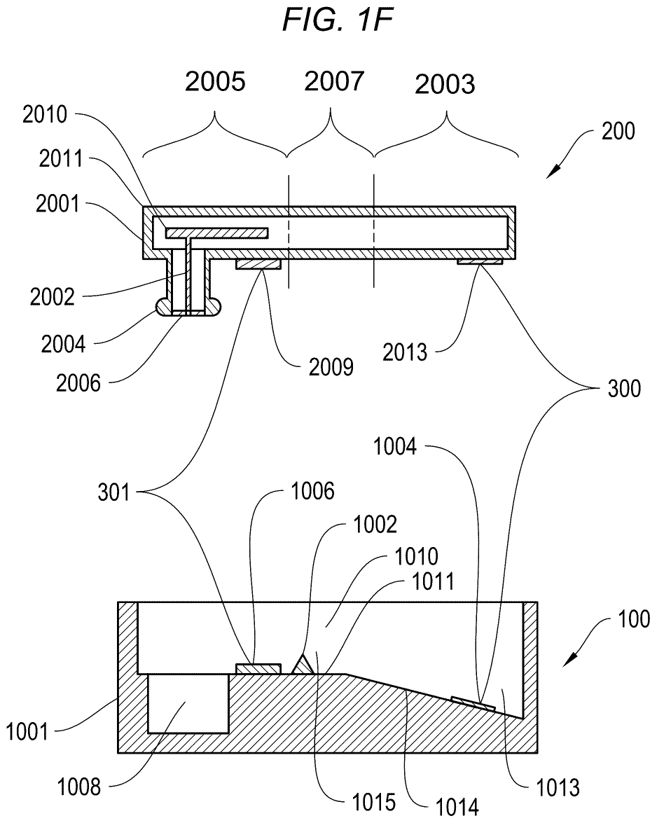

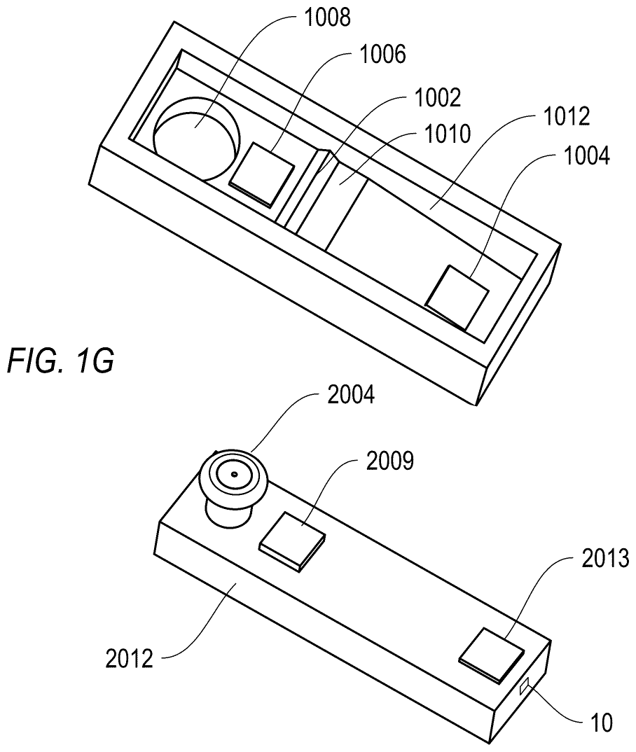

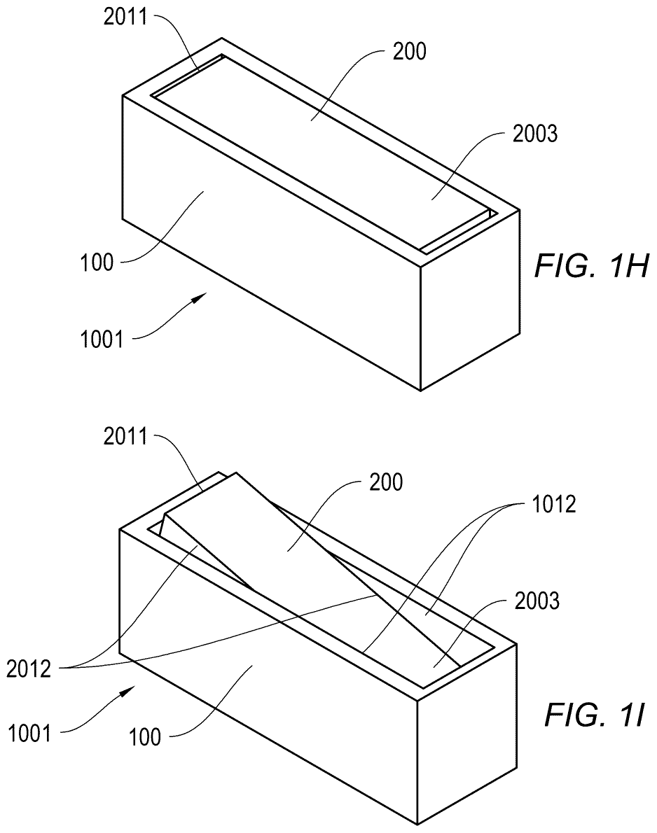

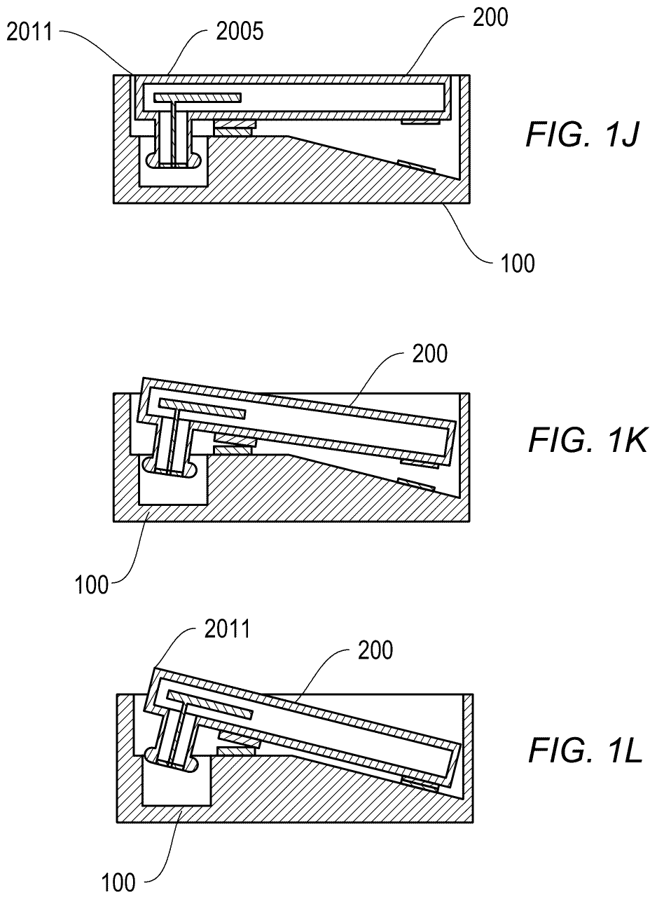

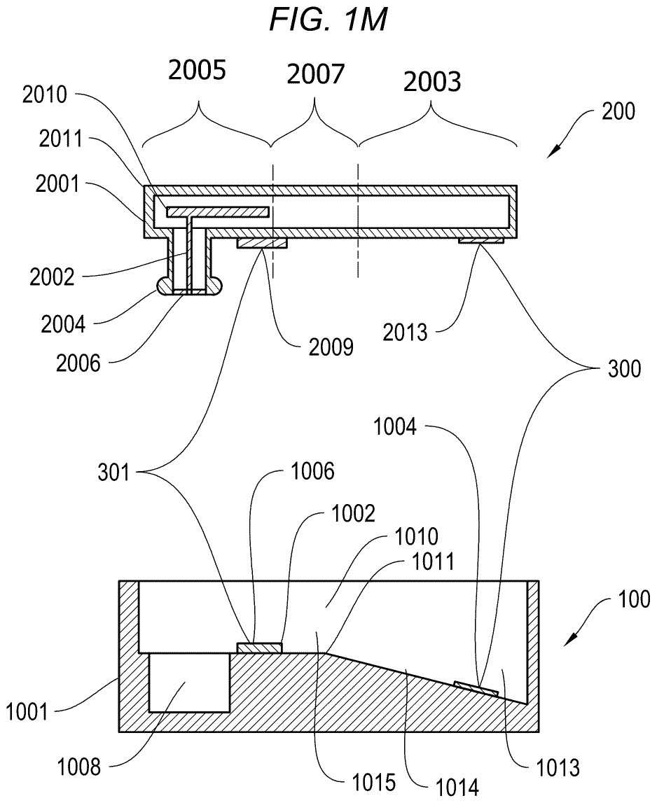

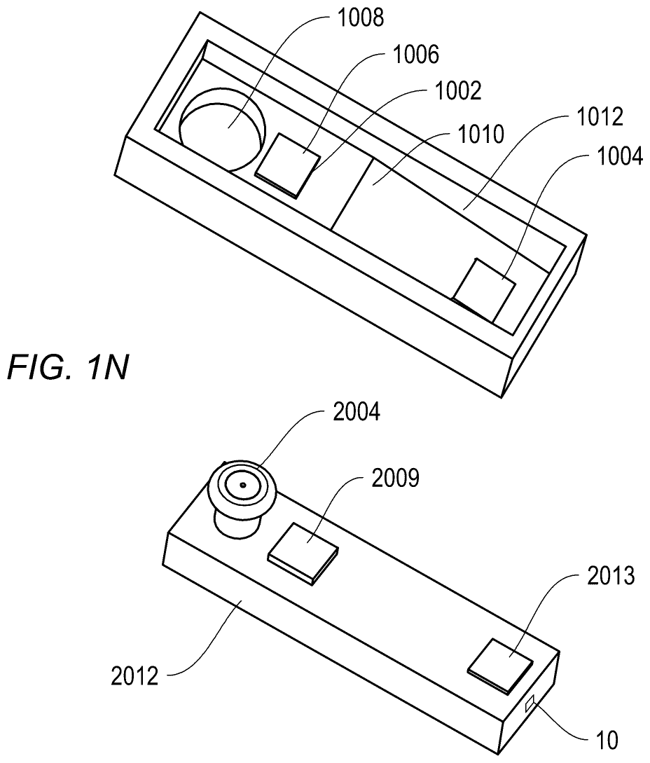

### System 1000/FIGS. 1A-1G

A system according to one or more embodiments will now be described with reference to the accompanying drawings. In one implementation, the system is system 1000. System 1000 is shown in FIGS. 1A-1G and has earpiece holder 100, earpiece 200, releasable fastener 300, and releasable fastener 301.

Earpiece 200 has earpiece body 2001 and an audio transmitter 2002. Earpiece body 2001 has second portion 2003, first portion 2005, and third portion 2007. In FIG. 1F, the portions are designated by brackets and separated by broken lines. The broken lines designate imaginary lines that delineate the respective portions from each other for reference purposes. In the example shown, second portion 2003, first portion 2005, and third portion 2007 are similar sizes and designate the right, middle, and left portions, respectively, of the earpiece body 2001. However, it is noted that, alternative embodiments, the portions of earpiece body 2001 may be located in different locations and occupy different parts of the earpiece body 2001 and/or may be different sizes.

Third portion 2007 is between second portion 2003 and first portion 2005 such that, when third portion 2007 pivots about fulcrum 1002, second portion 2003 and first portion 2005 move in opposing directions relative to each other. However, in alternative embodiments, second portion 2003, first portion 2005, and third portion 2007 may have another orientation relative to each other.

Earpiece holder 100 has housing 1001. Housing 1001 has fulcrum 1002, earpiece body support 1006, and earpiece body support 1004.

Fulcrum 1002 is engageable with third portion 2007 of earpiece body 2001 such that earpiece body 2001 can pivot about the fulcrum 1002 between a first position (shown in FIG. 1C) and a second position (shown in FIG. 1E). In other words, third portion 2007 provides a pivot point for earpiece body 2001, and the earpiece body 2001 can pivot about the fulcrum 1002 to move second portion 2003 from its “up” position shown in FIG. 1C to its “down” position shown in FIG. 1E while first portion 2005 moves in the opposing direction from its “down” position shown in FIG. 1C to its “up” position shown in FIG. 1E. As third portion 2007 (the pivot point) is between second portion 2003 and first portion 2005, the combination of the earpiece and earpiece holder is said to provide a first class lever. However, in alternative embodiments, the pivot point of the earpiece and fulcrum of the earpiece holder may be configured differently.

Earpiece body support 1006 is disposed a distance from fulcrum 1002 and configured to engage first portion 2005 of earpiece body 2001 when earpiece body 2001 in the first position shown in FIG. 1C. Specifically, earpiece body support 1006 is disposed such that fulcrum 1002 is between earpiece body support 1004 and earpiece body support 1006. In alternative embodiments, earpiece body support 1006 may be any portion of housing 1001 that blocks or limits further movement of first portion 2005 when first portion 2005 reaches earpiece body support 1006 after having been pivoted towards earpiece body support 1006 by the corresponding movement of earpiece body 2001 from the second position (FIG. 1E) to the first position (FIG. 1C). For illustrative purposes, fulcrum 1002 and earpiece body support 1006 are shown as separate structures which are both connected to the base wall (i.e. floor) of fulcrum cavity 1010. However, in alternative embodiments, fulcrum 1002 and earpiece body support 1006 may be part of a single member which is disposed about the base wall of fulcrum cavity 1010, as shown in FIGS. 1J-1N, and discussed later with respect to system 1001. In yet alternative embodiments, earpiece body support 1006 and fulcrum 1002 may be configured and/or positioned differently.

Earpiece body support 1004 is disposed a distance from the fulcrum 1002 and configured to engage second portion 2003 of earpiece body 2001 when earpiece body 2001 is in the second position, i.e. when second portion 2003 is in the down position shown in FIG. 1E. Earpiece body support 1004 is a portion of housing 1001 that blocks or limits further movement of second portion 2003 when second portion 2003 reaches earpiece body support 1004 (shown in FIG. 1E) after having been pivoted towards earpiece body support 1004 from its up position.

Releasable fastener 300 is configured for releasably attaching second portion 2003 of earpiece body 2001 to earpiece body support 1004 when earpiece body 2001 is in the second position. In the example shown in FIGS. 1A-1G, releasable fastener 300 is made up of earpiece body support 1004 and coupler 2013 which are couplers that interact with each other to releasably attach second portion 2003 of earpiece body 2001 to earpiece holder 100. In this manner, earpiece body support 1004 provides a function of supporting earpiece body 2001 and another function of releasably attaching to coupler 2013. In alternative embodiments, releasable fastener 300 may be configured for releasably attaching first portion 2005 of earpiece body 200 to earpiece holder 100. In such an example alternative embodiment, releasable fastener 300 may be disposed at a location such that it is configured for releasably attaching the distal end of the earpiece body 200 present on second portion 2005 (e.g. the left-most vertical surface of earpiece body 200 shown in FIG. 1C) to the distal end of a cavity of earpiece holder 100 (e.g. the left-most vertical surface of cavity 1011). In yet alternative embodiments, releasable fastener 300 may be configured for releasably attaching third portion 2007 of earpiece body 200 to earpiece holder 100. In such an example alternative embodiment, releasable fastener 300 may be disposed at a location such that it is configured for releasably attaching a sidewall 2012 of earpiece body 200 present on third portion 2007 to a corresponding sidewall 1012 of earpiece holder 100. In yet alternative embodiments, releasable fastener 300 may be configured for releasably attaching any part of earpiece body 200 to any part of earpiece holder 100.

In alternative embodiments, releasable fastener 300 may be configured in other manners. For example, Releasable fastener 300 may be configured in any manner that secures earpiece 200 to earpiece holder 100 when earpiece 200 is in the second position shown in FIG. 1E. For example, the interacting couplers of releasable fastener 300 may be disposed at any location(s) that allow releasable fastener 300 to secure earpiece 200 to earpiece holder 100 when earpiece 200 in the second position shown in FIG. 1E.

For example, releasable fastener 300 may have a pair of interacting couplers, wherein one of the couplers is fixed to earpiece holder 100 (sometimes referred to herein as an ‘earpiece holder-side coupler’) and the other coupler is fixed to earpiece 200 (sometimes referred to herein as an ‘earpiece-side coupler’). Non-limiting examples of structures which may be used to provide releasable fastener 300 include interacting magnets, a magnet and a magnetic material (e.g. iron, nickel, or cobalt), adhesive, hook/loop (e.g. Velcro®), vacuum devices (e.g. suction cup), tongue and groove (e.g. Ziplock®), synthetic seta (e.g. synthetic gecko foot), or any structure(s) configured to provide attachment by Van der Waals force, ionic bond, or other transitory bonds. Other structures for providing a releasable fastener (also known to those skilled in the art of fastening as a ‘reusable fastener’) are well known. Releasable fastener 300 is configured with an attachment strength such that the interacting couplers thereof can be detached from each other by the user's hand or fingers (e.g. by pivoting the earpiece). As an example, releasable fastener 300 may have a magnet, or other component(s) of a pair of interacting couplers, disposed about an interface of earpiece body support 1004 and second portion 2003 that is formed when the earpiece 200 is in the second position shown in FIG. 1E.

Releasable fastener 301 is configured for releasably attaching first portion 2005 of earpiece body 2001 to earpiece body support 1006 when earpiece body 2001 is in the first position. Releasable fastener 301 is configured with an attachment strength such that the interacting couplers thereof can be detached from each other by the user's hand or fingers (e.g. by pivoting the earpiece). In the example shown in FIGS. 1A-1G, releasable fastener 301 is made up of earpiece body support 1006 and coupler 2009 which are couplers that interact with each other to releasably attach first portion 2005 of earpiece body 2001 to earpiece holder 100. In this manner, earpiece body support 1006 provides a function of supporting earpiece body 2001 and another function of releasably attaching to coupler 2009. However, releasable fastener 301 may be configured differently. For example, releasable fastener 301 may be configured in any manner that secures earpiece 200 to earpiece holder 100 when earpiece 200 is in the first position shown in FIG. 1C. In alternative embodiments, releasable fastener 301 may be configured for releasably attaching second portion 2003 of earpiece body 200 to earpiece holder 100. In such an example alternative embodiment, releasable fastener 301 may be disposed at a location such that it is configured for releasably attaching the distal end of the earpiece body 200 present on second portion 2003 (e.g. the right-most vertical surface of earpiece body 200 shown in FIG. 1C) to the distal end of a cavity of earpiece holder 100 (e.g. the right-most vertical surface of cavity 1013). In yet alternative embodiments, releasable fastener 301 may be configured for releasably attaching third portion 2007 of earpiece body 200 to earpiece holder 100. In such an example alternative embodiment, releasable fastener 301 may be disposed at a location such that it is configured for releasably attaching a sidewall 2012 of earpiece body 200 present on third portion 2007 to a corresponding sidewall 1012 of earpiece holder 100. In yet alternative embodiments, releasable fastener 301 may be configured for releasably attaching any part of earpiece body 200 to any part of earpiece holder 100, such as configured for releasably attaching a bottom wall or sidewall of earpiece body 200 to a respective bottom wall or sidewall of earpiece holder 100.

Releasable fastener 301 may be a magnetic fastener (e.g. magnetic clasp), for example, by providing one or both of earpiece body support 1006 and coupler 2009 as a magnet. Alternatively, releasable fastener 301 may have any of the interacting couplers or other structures described herein with respect to releasable fastener 300. As an example, releasable fastener 301 may have a magnet, or other component(s) of a pair of interacting couplers, disposed about an interface of earpiece body support 1006 and first portion 2005 that is formed when earpiece body 2001 is in the first position shown in FIG. 1C.

In alternative embodiments, releasable fastener 301 may be configured in other manners. For example, releasable fastener 301 may be configured in any manner that secures earpiece 200 to earpiece holder 100 when earpiece 200 is in the first position shown in FIG. 1C. For example, the interacting couplers of releasable fastener 301 may be disposed at any location(s) that allow releasable fastener 301 to secure earpiece 200 to earpiece holder 100 in the first position shown in FIG. 1C.

Earpiece body 2001 has a housing for supporting audio transmitter 2002 and interacting with earpiece holder 100. In general, earpiece body 2001 is made of first portion 2005, second portion 2003, and third portion 2007. Third portion 2007 of earpiece body 2001 is a portion of the housing that interacts with fulcrum 1002 of earpiece holder 100 and provides a pivot point about which earpiece body 2001 can pivot. In order to pivot about fulcrum 1002, third portion 2007 may be configured with a surface that interfaces with fulcrum 1002 and limits pivoting movement to a single axis of rotation about fulcrum 1002, such as a flat surface provided by third portion 2007 which interfaces with, and pivots about, an elongated edge provided by fulcrum 1002. However, in alternative embodiments, earpiece body 2001 and/or third portion 2007 may be configured differently. Other configurations for providing a pivot point about which earpiece body 2001 can pivot about fulcrum 1002 include one or more members that, collectively, provide a plurality of contact points for contacting the fulcrum, such as a plurality of contact points spaced apart from each other a sufficient distance to stabilize the pivoting of the earpiece body on the fulcrum such that off-axis pivoting (i.e. pivoting about an axis other than the axis that the earpiece body pivots to move from the first position to the second position and vice-versa) is prevented or reduced.

When earpiece 200 is pivoting about fulcrum 1002 between the first position and the second position, and not supported by either earpiece body support 1004 or earpiece body support 1006, earpiece 200 is stabilized against sliding about fulcrum 1002 (e.g. lateral or longitudinal movement) and/or rotating about fulcrum 1002 by the following configuration of system 1000. Opposing side walls 1012 of fulcrum cavity 1010 are spaced apart from each other substantially the same distance as opposing sidewalls 2012 of earpiece 200 are spaced apart from each other to limit movement of earpiece 200 when in fulcrum cavity 1010. However, in alternative embodiments, the system is configured differently. For example, the earpiece 200 may comprise one or members (e.g. sidewalls 2012) that contact one or more members (e.g. side walls 1012) of the earpiece holder 100 to prevent lateral and/or longitudinal sliding of the earpiece 200 within the fulcrum cavity 1010.

Audio transmitter 2002 of earpiece 200 has an audio signal transmitter 2010 and audio sound transducers which are microphone 10 and audio driver 2006. The audio signal transmitter 2010 is configured for sending and receiving audio signals to/from a computing device (e.g. cellular phone, smart phone, or tablet PC). In alternative embodiments, the audio transmitter of the earpiece may be or have any one or any combination of the following: a microphone, a speaker, an analog audio (e.g. radio wave) signal receiver, an analog audio signal sender, a digital audio (e.g. Bluetooth) signal receiver, and/or a digital audio signal sender. It is noted that “transmitter” means sender and/or receiver.

Audio driver 2006 is an electrodynamic speaker driver, which is a transducer configured for converting audio signals into acoustic waves.

Microphone 10 is an audio sound transducer configured for converting acoustic waves into audio signals.

Audio signal transmitter 2010 of audio transmitter 2002 is a wireless transmitter such as a radio frequency (e.g. Bluetooth or Wi-Fi) transmitter configured to convert analog audio signals to digital audio signals and/or vice-versa and sends and receives digital audio signals to and from a computing device (e.g. cellular phone, smart phone, or tablet PC). In alternative embodiments, the audio signal transmitter may be configured differently. For example, the audio transmitter may be a wired transmitter such as a pair of electrically conductive wires that sends and/or receives analog or digital audio signals to/from the computing device In yet alternative embodiments, the audio signal transmitter may be configured to send audio signals to a device (e.g. computing device) or receive audio signals from a device (e.g. computing device). In yet alternative embodiments, the audio signal transmitter may be configured to send and/or receive audio signals to a device other than the computing device (e.g. earpiece holder 100).

In alternative embodiments, the audio transmitter of earpiece 200 is configured differently. For example, the audio transmitter may have at least one audio transducer and at least one audio signal transmitter. The at least one audio signal transmitter may be configured for sending audio signals to a computing device and/or receiving audio signals from a computing device. The at least one audio sound transducer (e.g. microphone and/or audio driver) may be configured for converting audio signals into acoustic waves and/or converting acoustic waves into audio signals.

Earpiece holder 100 has a cavity in which fulcrum 1002 is disposed, referred to herein as fulcrum cavity 1010. Additionally, fulcrum cavity 1010 is configured to hold earpiece 200 therein. More specifically, fulcrum cavity 1010 is configured as such that, when earpiece body 2001 pivots about fulcrum 1002, a certain portion(s) of earpiece body 2001 is contained within fulcrum cavity 1010 when the earpiece 200 is in the first position and protrudes from fulcrum cavity 1010 when the earpiece is in the second position. Fulcrum cavity 1010 may be configured as such by tailoring the size and shape of fulcrum cavity 1010. Details of such a configuration follow.

Fulcrum cavity 1010 is configured such that when earpiece body 2001 is in the second position shown in FIG. 1E, second portion 2003 is inside fulcrum cavity 1010 and a part 2011 (i.e. a portion) of first portion 2005 protrudes from fulcrum cavity 1010. By this configuration, when part 2011 of first portion 2005 protrudes from fulcrum cavity 1010, the user may easily grasp or pull on the protruding part 2011 of first portion 2005 to remove earpiece 200 from fulcrum cavity 1010. As shown in the figure, part 2011 of first portion 2005 that protrudes from fulcrum cavity 1010 when earpiece body 2001 is in the second position is a longitudinal end of earpiece body 2001. As shown in FIG. 1C, part 2011 is at the left-most distal end of the earpiece body 200. However, in alternative embodiments, part 2011 may be any graspable portion, such as a lifting (or liftable) edge.

However, in alternative embodiments, the part of first portion 2005 that protrudes from fulcrum cavity 1010 when earpiece body 2001 is in the second position may be a different part of earpiece body 2001. Additionally, rather than only part 2011 of first portion 2005 protruding from fulcrum cavity 1010 when earpiece body 2001 is in the second position, at least a part (i.e. at least a portion) of first portion 2005 may protrude from fulcrum cavity 1010, such as first portion 2005 in its entirety. In yet alternative embodiments, fulcrum cavity 1010 may be configured as such that, when earpiece body 2001 pivots about fulcrum 1002, a certain portion(s) of earpiece body 2001 is contained within fulcrum cavity 1010 when the earpiece 200 is in the first position and/or protrudes from fulcrum cavity 1010 when the earpiece is in the second position, such as a portion of the earpiece body other than first portion 2005.

Fulcrum cavity 1010 is further configured such that when earpiece body 2001 is in the first position shown in FIG. 1C, part 2011 of first portion 2005 is in fulcrum cavity 1010 and part 2011 of first portion 2005 does not protrude from fulcrum cavity 1010. Fulcrum cavity 1010 is further configured such that when earpiece body 2001 is in the first position shown in FIG. 1C, second portion 2003 is in fulcrum cavity 1010 and second portion 2003 does not protrude from the fulcrum cavity 1010. By this configuration, when earpiece body 2001 is in the first position, neither second portion 2003 nor part 2011 of first portion 2005 protrudes from fulcrum cavity 1010, and earpiece 200 is securely contained within fulcrum cavity 1010 to prevent inadvertent catching of ends of earpiece 200 that might pull earpiece body 2001 from fulcrum cavity 1010 to disengage earpiece 200 from earpiece holder 100.

However, in alternative embodiments, rather than only part 2011 of first portion 2005 being in, and not protruding from, fulcrum cavity 1010 when earpiece body 2001 is in the first position, at least a part (i.e. at least a portion) of first portion 2005 may be in, and not protruding from, fulcrum cavity 1010. For example, first portion 2005 in its entirety may be in, and not protruding from, fulcrum cavity 1010 when earpiece body 2001 is in the first position. In yet alternative embodiments the system may be configured differently.

Earpiece 200 has an ear interface 2004 for interfacing with the ear of a user. Ear interface 2004 is disposed in first portion 2005 of earpiece 200. As shown in the figures, ear interface 2004 has a ring for providing a snug fit in the user's ear. However, in alternative embodiments, the ear interface may omit the ring and may be configured in any other manner for interfacing with a user's ear. Additionally, in alternative embodiments, the ear interface of earpiece 200 may be in a location other than first portion 2005.

Earpiece holder 100 has a cavity for receiving the ear interface of earpiece 200, referred to herein as ear interface cavity 1008. Ear interface 2004 of earpiece 200 is in ear interface cavity 1008 when earpiece body 2001 is in the first position shown in FIG. 1C. As discussed above, ear interface 2004 of earpiece 200 is part of first portion 2005 of earpiece body 2001 and is on the opposing side of third portion 2007, relative to first portion 2005. As third portion 2007 pivots about fulcrum 1002 to raise second portion 2003 to the first position shown in FIG. 1C, first portion 2005 (or at least the portion thereof having the ear interface) is lowered into (or further into) ear interface cavity 1008.

Specifically, ear interface cavity 1008 is recessed in cavity wall 1011 of fulcrum cavity 1010, noting that cavity wall 1011 is the base wall (i.e. floor) of fulcrum cavity 1010. Said another way, ear interface cavity 1008 is a recess in cavity wall 1011. Configured in this manner, earpiece body 2001 of earpiece 200 can be placed in fulcrum cavity 1010 of earpiece holder 100, and earpiece body 2001 can pivot about fulcrum 1002 to raise and lower first portion 2005, and the portion thereof containing ear interface 2004, in ear interface cavity 1008. However, in alternative embodiments, ear interface cavity 1008 may be in another location or may be omitted.

Earpiece holder 100 has side walls 1012 that act as guides for earpiece 200 such that when earpiece 200 is placed in the fulcrum cavity 1010, side walls 1012 guide earpiece 200 into a position in which the third portion 2007 contacts fulcrum 1002. Specifically, side walls 1012 of earpiece holder 100 are spaced from each other a distance such that when earpiece 200 is placed between side walls 1012 the third portion 2007 can contact fulcrum 1002. Additionally, the side walls 1012 of earpiece holder 100 are spaced from each other a distance such that when earpiece 200 is placed inside the fulcrum cavity 1010 and the third portion 2007 is contacted with fulcrum 1002, the side walls 1012 prevent earpiece 200 from moving longitudinally and/or laterally a distance that would cause the third portion 2007 from disengaging with fulcrum 1002. Specifically, the side walls 1012 of fulcrum cavity 1010 are spaced apart from each other substantially the same distance as sidewalls 2012 from earpiece 200 are spaced apart from each other to limit movement of earpiece 200 when in fulcrum cavity 1010. In this configuration, the only movement of earpiece 200 that can disengage third portion 2007 from fulcrum 1002 is vertical movement of the earpiece, such as by pulling up on part 2011. However, in alternative configurations, earpiece holder 100 and/or side walls 1012 may be configured differently. For example, side walls 1012 may be spaced from each other a distance that does not provide any of the functions described above.

Fulcrum cavity 1010 of earpiece holder 100 has three portions: 1) a portion 1015 in which the fulcrum 1002 is disposed, 2) ear interface cavity 1008 configured for receiving the ear interface of earpiece 200, and 3) cavity 1013 for receiving the second portion 2003 of earpiece 200. Ear interface cavity 1008 and cavity 1013 are portions of fulcrum cavity 1010 that are deeper than portion 1015. As described above, ear interface cavity 1008 is more deeply recessed in order to accept the ear interface of earpiece 200. As described below, cavity 1013 is more deeply recessed in order to receive the second portion 2003 of earpiece 200 when earpiece 200 is in the second position shown in FIG. 1E.

Earpiece holder 100 has cavity 1013 recessed in cavity wall 1011 of fulcrum cavity 1010. Said another way, cavity 1013 is a recess in cavity wall 1011. More specifically, cavity 1013 is a deeper portion of fulcrum cavity 1010, relative to portion 1015 of fulcrum cavity 1010 which contains fulcrum 1002, and has cavity wall 1014 set at an incline such that cavity 1013 is tapered. It is noted that cavity wall 1014 is a base wall (or floor) of fulcrum cavity 1010. Configured in this manner, earpiece body 2001 of earpiece 200 can be placed in fulcrum cavity 1010 of earpiece holder 100, and earpiece body 2001 can pivot about fulcrum 1002 to lower second portion 2003 down into cavity 1013. The more deeply recessed nature of cavity 1013, relative to portion 1015, provides a greater degree of pivoting movement of earpiece 200 on fulcrum 1002 before engaging second portion 2003 with the bottom of the fulcrum cavity 1010. This greater degree of pivoting movement acts to raise first portion 2005 higher than it would otherwise be allowed to lift, if not for the deeper recess of cavity 1013, providing an easily accessible (raised) portion for user to pluck the earpiece 200 out of the earpiece holder 100 to use earpiece 200. This configuration can allow from part 2011, when earpiece body 2001 is in the first position shown in FIG. 1C, to be in and not protrude from fulcrum cavity 1010, while, when earpiece body 2001 is in the second position shown in FIG. 1E, to protrude from fulcrum cavity 1010, without the need for an excessively tall earpiece holder 100.

However, in alternative embodiments, fulcrum cavity 1010 may be configured differently, such as by omitting a more deeply recessed car interface cavity 1008 and/or cavity 1013.

System 1000 may be used and/or further configured to implement any of the methods taught herein.

While FIGS. 1A-1G show example features of system 1000, in some implementations, the present technology contemplates a system which includes additional features, fewer features, different features, or differently arranged features than those depicted in FIGS. 1A-1G or described with respect to FIGS. 1A-1G. For example, the present technology contemplates a system comprising any one or any combination of the features and/or configurations shown in FIGS. 1A-1G or described with respect to FIGS. 1A-1G. For example, it is noted that, in the illustrated embodiments taught herein, certain features of the earpiece body 200 (e.g. ear interface, lifting edge, coupler of releasable fastener, etc,) are described as being in or on the second portion 2003, first portion 2005, or third portion 2007, the present technology contemplates embodiments in which any one or any combination of such features are provided at a different location.

### System 1001/FIGS. 1H-1N

A system according to one or more embodiments will now be described with reference to the accompanying drawings. In one implementation, the system is system 1001. System 1001 is shown in FIGS. 1H-1N and has earpiece holder 100, earpiece 200, releasable fastener 300, and releasable fastener 301.

The system is configured the same as system 1000, except that the fulcrum 1002 of system 1001 and the earpiece holder-side coupler of the releasable fastener 301 of system 1001 are respective portions of a single member disposed about the base wall of fulcrum cavity 1010. Specifically, in system 1001, fulcrum 1002 is an edge of a platform and the earpiece holder-side coupler of the releasable fastener 301 (earpiece body support 1006 in this case) is a portion of the same platform. For example, the platform may be a magnet in which part of the magnet acts as earpiece body support 1006 and/or the earpiece holder-side coupler of the releasable fastener 301, and in which the edge of the magnet provides fulcrum 1002. In such a configuration, the magnet may provide both the earpiece body support 1006 and the earpiece holder-side coupler of releasable fastener 301. It is also noted that, while earpiece body support 1006 is disposed a distance from fulcrum 1002, the section of the platform that connects earpiece body support 1006 to fulcrum 1002 also contacts and supports the earpiece.

In this configuration, manufacturing of the earpiece holder 100 is simplified through the use of a single member which provides both the earpiece body support 1006 and the fulcrum 1002, and/or provides both the earpiece holder-side coupler of releasable fastener 301 and the fulcrum 1002.

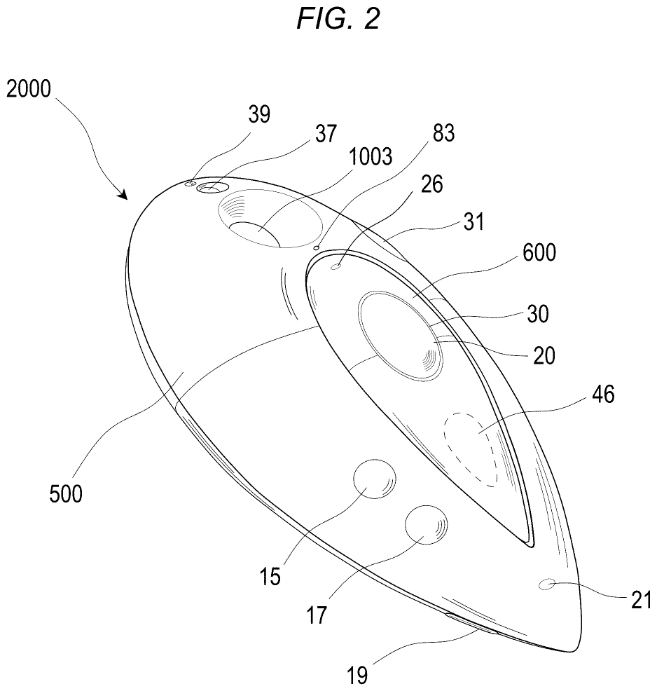

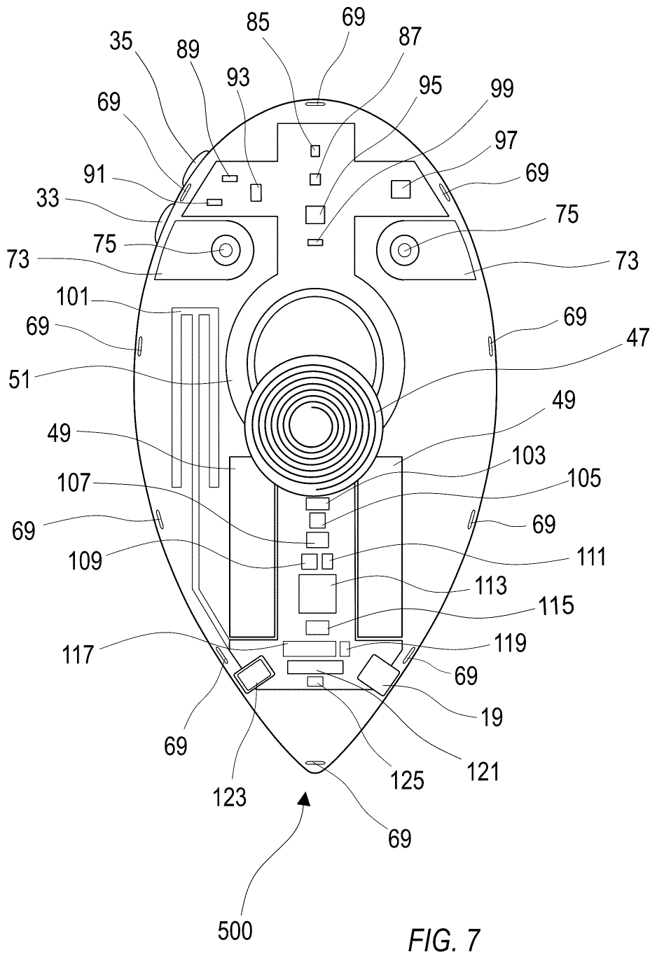

### System 2000/FIGS. 2-15

A system according to one or more embodiments will now be described with reference to the accompanying drawings. In one implementation, the system is system 2000. System 2000 is shown in FIGS. 2-15 and has earpiece holder 500, earpiece 600, releasable fastener 300 and releasable fastener 301. System 2000 includes all of the general features described with respect to system 1000 and system 1001, but includes specific implementations of such as well as additional features.

Earpiece holder 500 has each of the components present in earpiece holder 100 and described above with respect to FIGS. 1A-1G. Specifically, earpiece holder 500 has specific implementations of housing 1001, fulcrum 1002, earpiece body support 1004, earpiece body support 1006, ear interface cavity 1008, fulcrum cavity 1010, and cavity wall 1011, each having all of the configuration and features described with respect to earpiece holder 100, unless otherwise noted in the descriptions that follows. In alternative embodiments, earpiece holder 500 may be configured in any alternative manner described herein, such as in the descriptions accompanying system 1000 and/or earpiece holder 100. For example, any one or any combination of such components may be absent or configured differently.

Earpiece 600 has each of the components present in earpiece 200 and described above with respect to FIGS. 1A-1G. Specifically, earpiece 600 has specific implementations of earpiece body 2001, audio transmitter 2002, second portion 2003, first portion 2005, third portion 2007, part 2011, ear interface 2004, audio signal transmitter 2010, audio driver 2006, and microphone 10, each having all of the configuration and features described with respect to earpiece 200, unless otherwise noted in the descriptions that follow. In alternative embodiments, earpiece 600 may be configured in any alternative manner described herein, such as in the descriptions accompanying system 1000 and/or earpiece 200. For example, any one or any combination of such components may be absent or configured differently.

System 2000 has specific implementations of releasable fastener 300 and releasable fastener 301, respectively, previously described with respect to system 1000. Releasable fastener 301 is provided by magnet 16 on earpiece 600 and magnet 11 on earpiece holder 500 which interact to form a releasable fastener. Releasable fastener 300 is provided by magnet 12 on earpiece 600 and permanent magnet 27 and electromagnet 25 on earpiece holder 500 which interact to form a releasable fastener. However, in alternative embodiments, system 2000 may omit one or both of releasable fastener 301 and releasable fastener 300.

The first portion and second portion of earpiece 600 are portions of earpiece 600 on opposing ends of earpiece 600, relative to each other. When earpiece 600 pivots about the third portion, the first portion and second portion move in opposing directions. The first portion of earpiece 600 has part (i.e. a coupler) of the first releasable fastener 301 and the second portion of earpiece 600 has part (i.e. a coupler) of the second releasable fastener 300.

The third portion of earpiece 600 includes magnet 16. Magnet 16 provides a pivot point about which earpiece 600 can pivot on the fulcrum of earpiece holder 500. Magnet 16 is disposed across both the first portion and third portion of earpiece 600 and thereby provides one component of releasable fastener 301 and also provides a pivot point about which earpiece 600 can pivot on the fulcrum of earpiece holder 500.

Earpiece holder 500 has magnetic fulcrum 29, which is a specific implementation of fulcrum 1002. Magnetic fulcrum 29 provides an attractive force for attracting magnet 16 (i.e. the pivot point) of earpiece 600.

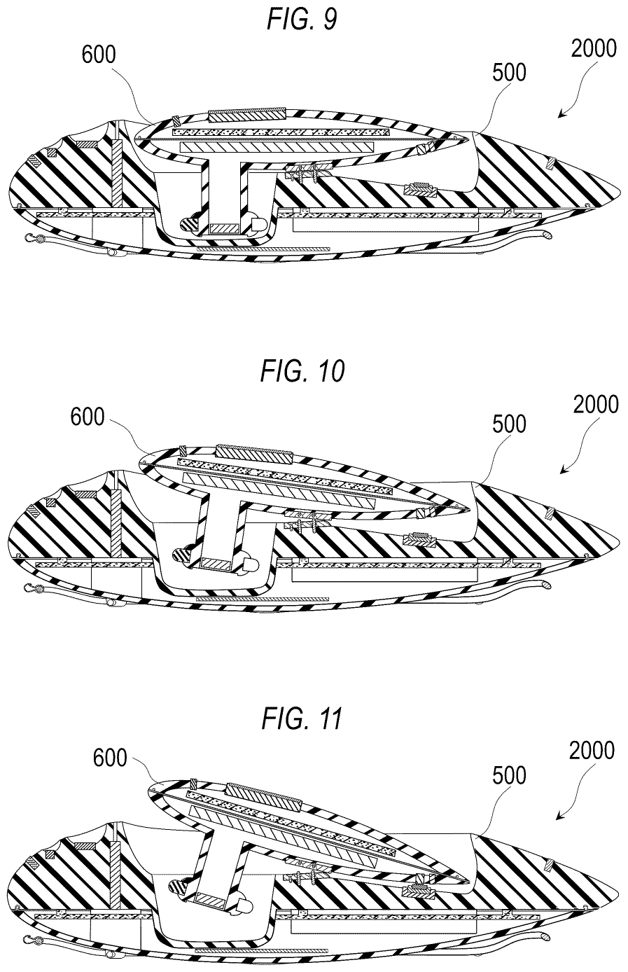

Earpiece holder 500 has magnet 11 as a specific implementation of earpiece body support 1006 and one component of releasable fastener 301. Magnet 11 is provided as a flat plate that makes flush contact with magnet 16 of the first portion of earpiece 600 and supports earpiece 600 (in combination with the fulcrum 29) when earpiece 600 is in the first position shown in FIG. 9. However, in alternative embodiments, the magnet may be configured differently, or the earpiece body support may have a supporting member other than a magnet.

Earpiece holder 500 has permanent magnet 27 which is a specific implementation of earpiece body support 1004 and one component (i.e. a coupler) of releasable fastener 300. Permanent magnet 27 is provided at the bottom of cavity 1005, near one end, such that it makes contact with magnet 12 of the first portion of earpiece 600 and supports earpiece 600 (in combination with the fulcrum 29) when earpiece 600 is in the second position shown in FIG. 11. However, in alternative embodiments, the magnet may be configured differently, or the earpiece body support may have a supporting member other than a magnet.

Releasable fastener 300 is provided by a magnetic clasp having magnet 12 which interacts with a magnet system having electromagnet 25 and permanent magnet 27 to form a functional clasp. Specifically, magnet 12 is disposed about the first portion of earpiece 600 and electromagnet 25 and permanent magnet 27 are disposed about a portion of earpiece holder 5000 that provides an earpiece body support.

Releasable fastener 301 is provided by a magnetic clasp having magnet 16 and magnet 11 which interact to form a functional clasp. Specifically, magnet 11 is disposed about a portion of earpiece holder 500 that provides an earpiece body support, and magnet 16 is disposed across both the second portion of earpiece 600 and the third portion of earpiece 600 such that magnet 16 is attracted to both the earpiece body support (i.e. magnet 11) and magnetic fulcrum 29 described herein.

Earpiece holder 500 has main body 63 and back cover which combine to form a housing which is a specific implementation of housing 1001.

Earpiece holder 500 has cavity 1005 which is a specific implementation of fulcrum cavity 1010 of earpiece holder 100. Cavity 1005 has a base wall (i.e. floor) which is generally configured in the same or similar manner as cavity wall 1011 of earpiece holder 100.

Earpiece holder 500 has ear interface cavity 1008 which is generally configured in the same or similar manner as described above with respect to earpiece holder 100.

Additional details of the magnetic clasp which provides the releasable fastener 301 will now be described.

As described above, releasable fastener 301 of system 2000 is provided by a magnetic clasp having magnet 16 and magnet 11 which interact to form a functional clasp. Magnet 16 and magnet 11 are each configured as a flat magnet such that an interface is formed between the two magnets with a sufficient strength to maintain earpiece 600 in the first position, even if system 2000 is turned upside down or jostled while hanging on a lanyard.

Additional details of magnet 11 and magnet 16 will now be described.

The magnet 11 of earpiece holder 500 has a first portion that contacts a corresponding earpiece-side coupler of releasable fastener 301 (magnet 16) of earpiece 600 to act as a support for retaining the earpiece in the first position, and earpiece holder 500 also has a second portion that provides fulcrum 29. In other words, a single magnet provides both fulcrum 29 and the earpiece holder-side coupler of releasable fastener 301. In the configuration shown, fulcrum 29 is the edge of magnet 11 and the earpiece holder-side coupler of releasable fastener 301 is provided by a flat surface of magnet 16. Additionally, it is noted that charging circuit conductor 13 and charging circuit conductor 1009 are disposed at the surface of magnet 11, specifically, the portion which provides the earpiece holder-side coupler of releasable fastener 301. However, in alternative embodiments, magnet 11 may be configured differently, for example, may omit any one or any combination of the aforementioned features.

Magnet 16 of earpiece 600 has a portion that acts as an earpiece-side coupler of releasable fastener 301, which contacts and is supported by the earpiece holder-side coupler of releasable fastener 301 (i.e. the portion of magnet 11 discussed above). Magnet 16 of earpiece 600 also has a portion that pivots about fulcrum 29. In other words, a single magnet provides both the pivot point and the earpiece-side coupler of releasable fastener 301. In the configuration shown, the pivot point part of magnet 16 that contacts fulcrum 29, and the earpiece-side coupler releasable fastener 301 is provided by a flat surface of magnet 16 which contacts the corresponding portion of magnet 11 which provides the earpiece holder-side coupler of releasable fastener 301. Additionally, it is noted that charging circuit conductor 14 and charging circuit conductor 18 are disposed at the surface of magnet 16, specifically, the portion which provides the earpiece-side coupler of releasable fastener 301. However, in alternative embodiments, magnet 16 may be configured differently, for example, may omit any one or any combination of the aforementioned features.

Additionally or alternatively, it is noted that, as described herein, one of magnets 11 and 16 may be a magnetic material rather than a magnet.

Additional details of the magnetic clasp which provides releasable fastener 300 will now be described.

As described above, releasable fastener 300 of system 2000 is provided by a magnetic clasp having magnet 12 which interacts with a magnet system having electromagnet 25 and permanent magnet 27 to form a functional clasp.

Earpiece holder 500 has electromagnet 25 and permanent magnet 27 configured to maintain earpiece 600 in the second position, thereby functioning as part of the magnetic clasp which provides releasable fastener 300. Electromagnet 25 and permanent magnet 27 are disposed in cavity 1005.

Earpiece 600 has magnet 12 configured to interact with electromagnet 25 and permanent magnet 27, thereby functioning as another part of the magnetic clasp which provides releasable fastener 301. Magnet 12 is positioned near one end of the earpiece body of earpiece 600 such that, when the second portion of earpiece 600 is pivoted down to the second position shown in FIG. 11, magnet 12 comes into close proximity with electromagnet 25 and permanent magnet 27. It is noted that magnet 12 is disposed about the second portion of earpiece 600 and supports earpiece 600 (in combination with the fulcrum 29) when earpiece 600 is in the second position shown in FIG. 11.

Earpiece holder 500 is configured to control electromagnet 25 to magnetize and demagnetize electromagnet 25. Specifically, a controller of earpiece holder 500 is configured to turn on electromagnet 25 based on a determination that earpiece 600 is a specified position. Such control may be provided by a detection circuit configured to detect the specified position and then perform a respective step of control. As one example, the controller of earpiece holder 500 may be configured to turn on electromagnet 25 upon disconnection of charging circuit conductor 14 and charging circuit conductor 18 from charging circuit conductor 1009 and charging circuit conductor 13 (when connection of the circuit conductors is used as an indication that the earpiece 600 is the first position). As another example, the controller may be configured to perform the step of turning on (or off) the electromagnet 25 responsive to detection of the earpiece 600 by proximity sensor 1007, e.g. detection that earpiece 600 is stowed in earpiece holder 500 or is in the second position. As another example, the controller may be configured to perform the step of turning on (or off) the electromagnet 25 responsive to mechanical switch 23 being activated up earpiece 600 reaching the second position. Additionally or alternatively, the controller of earpiece holder 500 may be configured to turn on electromagnet 25 for period of time to retain earpiece 600 in the second position, and then switch off electromagnet 25, e.g., to allow earpiece 600 to automatically return to the first position as a result of the attractive forces of the force of magnet 11 and magnet 16.

In the embodiment shown in the FIGS. 2-15, the combined force of electromagnet 25 and permanent magnet 27, which attracts magnet 12, is sufficient to retain earpiece 600 in the second position, for example, by overcoming any attractive force from magnet 11 and magnet 16 that would otherwise cause earpiece 600 to pivot back to the first position. However, in alternative embodiments, earpiece holder 500 may comprise any configuration in which at least one magnet is provided to maintain earpiece 600 in the second position. For example, electromagnet 25 may be omitted and permanent magnet 27 may be of sufficient strength to maintain earpiece 600 in the second position. As anther example, magnet 27 may be omitted and electromagnet 25 may be of sufficient strength to maintain earpiece 600 in the second position. By retaining earpiece 600 in the second position, the system provides easier removal of the earpiece 600 from the holder earpiece holder 500. To return the earpiece 600 to the first position, a user can push near lifting edge 48 to bring magnet 11 in closer proximity to magnet 16 while distancing magnet 12 of earpiece 600 from electromagnet 25 and permanent magnet 27 such that mutual attraction of the corresponding magnet 11 and magnet 16 overcomes the mutual attraction of magnet(s) (25 and/or 27) to the corresponding portion of earpiece 600 (magnet 12).

In alternative embodiments, the system can omit one or both of releasable fastener 300 and releasable fastener 301. For example, the system may comprise releasable fastener 301 and not releasable fastener 300. In such an example, after a user pivots earpiece 600 to the second position shown in FIG. 11, the attractive force of interacting magnets of releasable fastener 301 may be configured to be sufficient to automatically cause earpiece 600 to pivot back to the first position shown in FIG. 9.

Additional details of the fulcrum of earpiece holder 500 will now be described.

Earpiece holder 500 has magnetic fulcrum 29. Magnetic fulcrum 29 provides the same fulcrum function as fulcrum 1002 described with respect to earpiece holder 100 of system 1000 and system 1001. Magnetic fulcrum 29 is made of a magnet for attracting the pivot point of the third portion of earpiece 600, noting that the pivot point of the third portion of earpiece 600 has a magnet (magnet 16) having oppositely-aligned polarity relative to magnetic fulcrum 29. Magnetic fulcrum 29 is configured such that that the pivot point of earpiece 600 (magnet 16) is biased to stay in contact with fulcrum 29 while the user pivots earpiece 600 about magnetic fulcrum 29 between the first position shown in FIG. 9 and the second position shown in FIG. 11. In alternative embodiments, the fulcrum of earpiece holder 500 may be configured differently. For example, the fulcrum of earpiece holder 500 may be a non-magnetic fulcrum, or only one of the fulcrum of earpiece holder 500 and the pivot point of the earpiece 600 may have a magnet and the other may have a magnetic material (e.g. iron, nickel, or cobalt) that is attracted to the magnet. In yet alternative embodiments, the fulcrum and the pivot point may not be secured or attracted to each other, or the system may comprise any releasable fastener configured for releasably attaching the fulcrum of earpiece holder 500 and the pivot point of earpiece 600, e.g. adhesive, hook/loop (e.g. Velcro®), vacuum devices (e.g. suction cup), tongue and groove (e.g. Ziplock®), synthetic seta (e.g. synthetic gecko foot), or any structure(s) configured to provide attachment by Van der Waals force, ionic bond, or other transitory bonds.

Earpiece holder 500 and earpiece 600 have additional components and configurations which will now be described.

The charging configuration of system 2000 will now be described.

System 2000 is configured to transfer power from earpiece holder 500 to earpiece 600. Specifically, earpiece 600 has battery 24 and earpiece holder 500 has battery 49 which provides a power source for charging battery 24 when earpiece 600 is stowed in earpiece holder 500. More specifically, earpiece 600 has a first set of conductors (14, 18) and earpiece holder 500 has a second set of conductors (1009, 13) which are disposed in respective locations about earpiece 600 and earpiece holder 500, respectively, such that the first set of conductors and the second set of conductors are electrically connected to each other when the earpiece 600 is in the first position (FIG. 9). The conductors are electrical terminals configured such that, when earpiece 600 is in the first position, contact is made between electrical terminals of earpiece 600 and electrical terminals earpiece holder 500. Additional details of this configuration will now be described.

Earpiece 600 has charging circuit conductor 14 and charging circuit conductor 18 which are electrical terminals configured to provide electrical power to earpiece 600 when they receive such electrical power externally (i.e. from charging circuit conductor 1009 and charging circuit conductor 13 described below).

Earpiece holder 500 has charging circuit conductor 1009 and charging circuit conductor 13 which are electrical terminals spatially oriented about earpiece holder 500 such that, when earpiece 600 is stowed in earpiece holder 500 in the first position (FIG. 9), charging circuit conductor 14 and charging circuit conductor 18 of earpiece 600 align with and are contacted with charging circuit conductor 13 and charging circuit conductor 1009, respectively. Charging circuit conductor 14 and charging circuit conductor 18 are springs biased outwardly to ensure stable contact with the respective terminals of earpiece 600 (i.e. charging circuit conductor 14 and charging circuit conductor 18). It is noted that charging circuit conductor 1009 and charging circuit conductor 13 provide a second set of conductors which are operably connected to battery 49 by electrical wires, which provides a power source for charging battery 24. In general, it is noted that conductors may be operably connected (e.g. to a battery) in any manner that allows transfer of electrical energy, such as by electrical wire or inductive coupling.

Configured as such, earpiece holder 500 can be used to charge earpiece 500 when earpiece 600 is stowed in earpiece holder 500. However, in alternative embodiments, the charging components are configured differently or omitted. For example, the first and second sets of conductors may be oriented such that charging occurs when the earpiece 600 is in a different position, or such that charging can occur when earpiece 600 is in a plurality of different positions. Alternatively, rather than contact-based terminals, a wireless (e.g. inductive) charging system may be implemented, which will be described later with respect to system 3000.

Earpiece holder 500 is configured to be rocked by the user while it is sitting on a surface. Additional details of this rocking configuration will now be described.

Earpiece holder 500 has a base on an opposing side of the earpiece holder, relative to the fulcrum, and comprises feet and a balancing portion on which earpiece holder 500 can balance when the earpiece holder 500 is placed on a horizontal surface 7000. Earpiece holder 500 is configured to be able to be rocked by the user, from the position of balancing to a stabilized position. Additional details of this configuration will now be described.

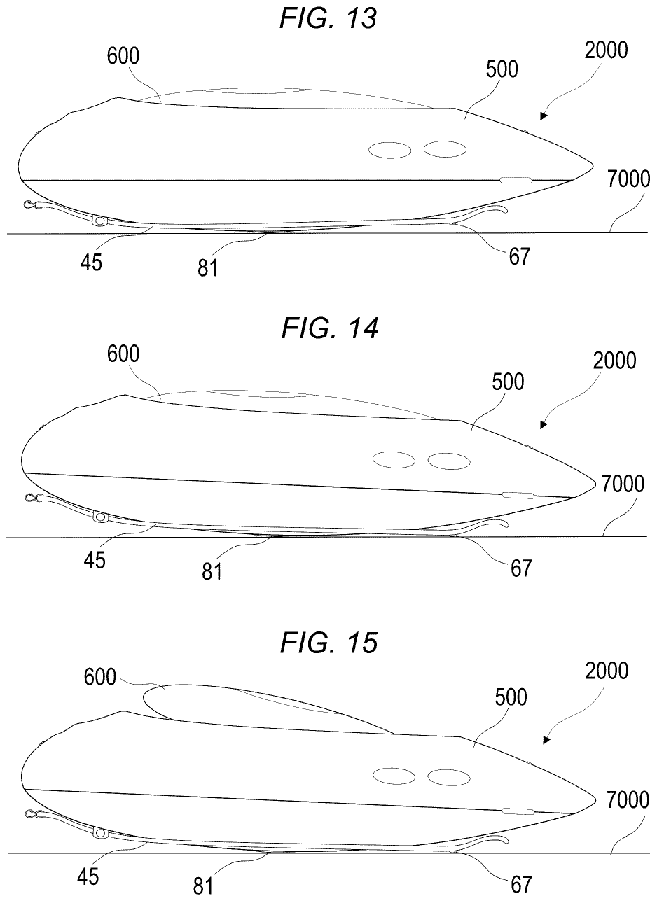

The housing of earpiece holder 500 has a base (the bottom surface earpiece holder 500 shown in FIGS. 13-15) that can rest on a horizontal surface 7000 and support the earpiece holder. Specifically, the base has a balancing portion and feet. The balancing portion is provided by contact patch 81. The feet are provided by robber dots 67. The balancing portion, provided by contact patch 81, is a portion of the earpiece holder housing on which earpiece holder 500 can balance when earpiece holder 500 is placed on a horizontal surface 7000, such as a tabletop, as shown in FIG. 13. The feet, provided by robber dots 67, are disposed a distance from the balancing portion and have a height (or projection distance from the housing of earpiece holder 500) such that when earpiece holder 500 is balanced on the horizontal surface 7000 by the balancing portion (contact patch 81), the balancing portion is lower than the feet, as shown in FIG. 13. The system 2000 as a whole as a center of gravity such that when the balancing portion rests on the horizontal surface, the ends (left and right ends shown in FIG. 13) and feet are elevated from the horizontal surface. The combination of the balancing portion and the feet are configured such that, when a downward force is applied over the feet (or otherwise applied laterally of the balancing portion) to rock earpiece holder 500 about the balancing portion, the feet are rocked in a downward direction to engage the horizontal surface 7000, as shown in FIG. 14 and FIG. 15. When the feet reach the horizontal surface 7000 after being rocked down by the user, as shown in FIG. 14 and FIG. 15, the contacting of the horizontal surface 7000 by the feet prevents further rocking in the downward direction. Additional details of the base, balancing portion, and feet will now be described.

As described above, the base of the housing of earpiece holder 500 has a contact patch 81 which provides a balancing portion on which earpiece holder 500 can balance. Specifically, contact patch 81 is a portion of a convex arc of the housing of earpiece holder 500 that sits under the center of gravity of earpiece holder 500. Earpiece holder 500 has feet provided by rubber dots 67. The feet are disposed on the same side of earpiece holder 500 as the balancing portion, protruding from the convex arc of the housing of earpiece holder 500, but are positioned higher than the balancing portion (at least when the earpiece holder is balanced on the horizontal surface 7000 by the balancing portion) such that the balancing portion (contact patch 81) is lower than the feet. Configured as such, when a downward force is applied to a portion of the earpiece holder distanced away from the balancing portion to rock the earpiece holder about the balancing portion, the feet are rocked in a downward direction to engage the horizontal surface 7000 (e.g. table top) and, by engaging the horizontal surface 7000 the feet prevent further rocking in the downward direction, as shown in FIG. 14 and FIG. 15.

Additionally, system 2000 is configured such that the same user motion which pivots earpiece 600 about the fulcrum of earpiece holder 500 can also cause earpiece holder 500 to rock in the manner described above. Details of this configuration will now be described.

The fulcrum of earpiece holder 500 (provided by magnetic fulcrum 29) and the balancing portion of earpiece holder (provided by contact patch 81) are arranged, relative to each other, such that a downward force applied by a user on press point area 46 can pivot earpiece 600 about the fulcrum and also pivot earpiece holder 500 about the balancing portion. Specifically, the releasable fastener (provided by magnets 11, 16) that releasably attaches earpiece holder 500 and earpiece 600 in the first position has an attachment strength that is stronger than the force required to pivot earpiece holder 500 about the balancing portion. By this configuration, when system 2000 rests on a horizontal surface 7000, as shown in FIG. 13, and then a relatively weak downward force is applied by a user on press point area 46, earpiece holder 500 rocks or pivots about the balancing portion from the balancing position (FIG. 13) until the feet engage the horizontal surface 7000 (FIG. 14), and an additional (relatively strong) downward force is applied on press point area 46 can cause earpiece 600 to pivot about the fulcrum of earpiece holder 500 to pivot earpiece 600 to the second position while the feet are engaged with the horizontal surface 7000 (FIG. 15). A more detailed explanation of this process will now be described.

When the earpiece 600 is stowed in (sometimes referred to herein as ‘mounted to’) earpiece holder 500 and earpiece holder 500 is placed on a flat horizontal surface 7000, as shown in FIG. 13, earpiece holder 500 will naturally wobble and/or spin about contact patch 81 due to any physical disturbance. In such context, when a user presses on press point 46 of earpiece 600 to pivot earpiece 600 from the first position to the second position, earpiece holder 500 will first react to the force by rocking upon its contact patch 81 until the feet (provided by rubber dots 67) contact the horizontal surface 7000, as shown in FIG. 14, causing the clothes clip 45, to which the feet are attached, to flex until it bottoms out on the housing of the earpiece holder 500 (specifically, the holder's rear cover 65), such that the earpiece holder 500 is now stabilized on the flat surface at three points including the balancing portion (provided by contact patch 81) and the feet (provided by rubber dots 67). Thus, a momentary tripod stance is achieved while pressing on the press point 46 of the earpiece 600 whilst mounted to the earpiece holder 500, facilitating removal and deployment of the earpiece 600 from the earpiece holder 500 in a stabilized freestanding position, on a horizontal surface 7000 such as a desk or table as shown in FIG. 15. This sequence is illustrated by progression through FIGS. 13, 14, and 15.

However, in alternative embodiments, system 2000 and/or earpiece holder 500 may omit such a rocking feature and/or feet, or the rocking feature and/or feet may be configured differently.

As can be seen in the figures, system 2000 as a whole, as well as each of earpiece holder 500 and earpiece 600, has an almond shape.

The almond shape of earpiece holder 500 will now be described in more detail.

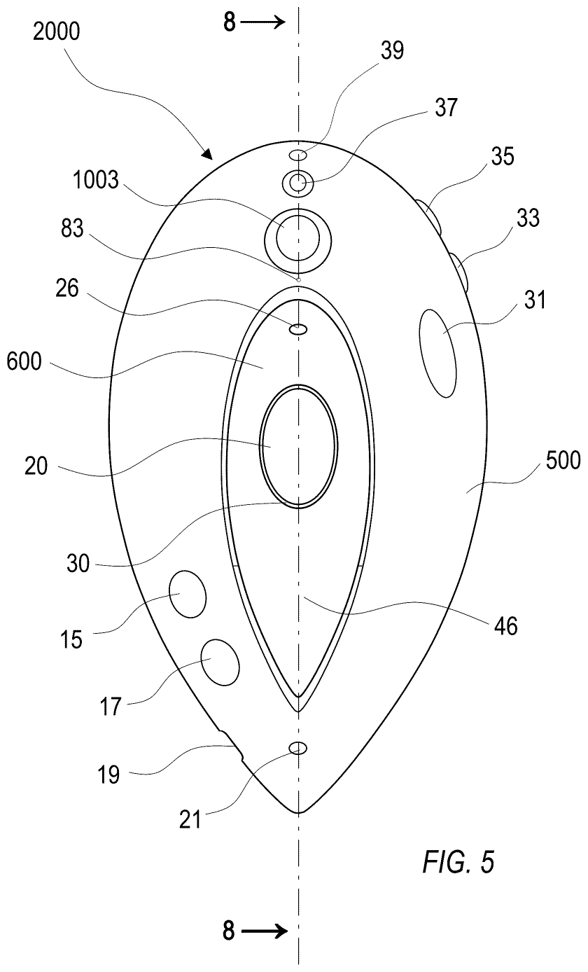

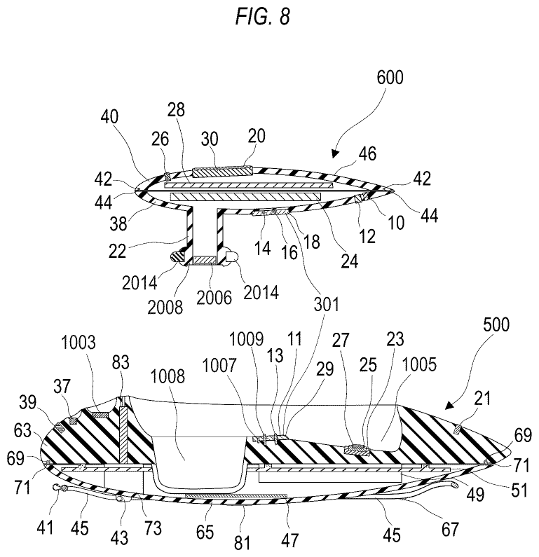

FIG. 8 depicts a side elevational sectional view system shown in FIG. 2, shown with the earpiece removed from the earpiece holder. It is noted that FIG. 5 shows the line from which the sectional view of each of earpiece 600 and earpiece holder 500 shown in of FIG. 8 is taken. However, it is further noted that FIG. 5 shows the system in the assembled view (i.e. with the earpiece 600 secured in earpiece holder 500), while FIG. 8 shows the earpiece 600 removed from the earpiece holder 500.

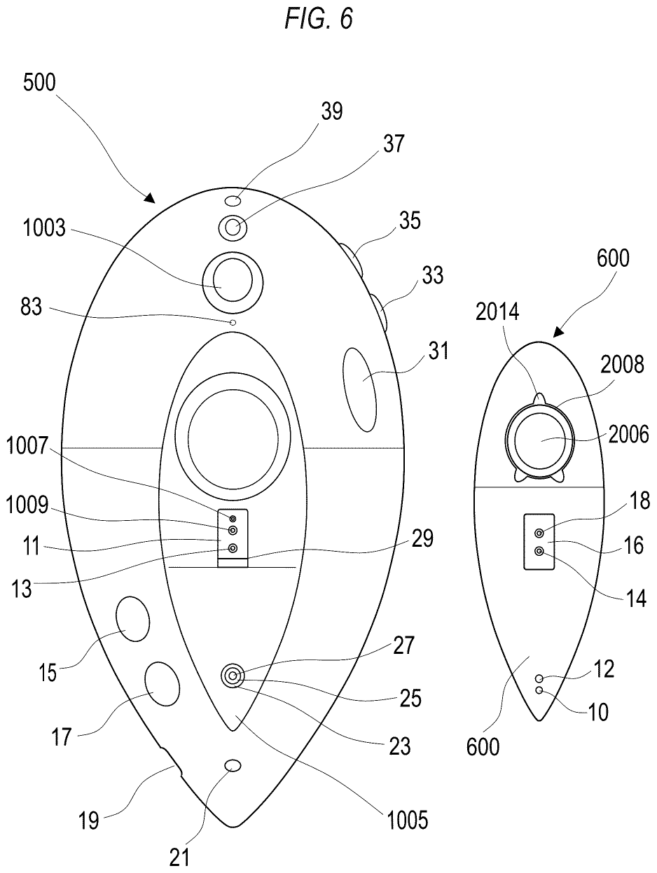

As described above, the base of the housing of earpiece holder 500 has a convex arc, of which contact patch 81 is a balancing portion. The housing of earpiece holder 500 has a central portion comprising the contact patch 81 as the balancing portion. The housing of earpiece holder 500 has a first end which is the right most part of earpiece holder 500 in FIG. 8 and the bottom most portion of earpiece holder 500 in FIG. 6. The housing of earpiece holder 500 has a second end which is the left most part of earpiece holder 500 in FIG. 8 and the topmost portion of earpiece holder 500 in FIG. 6. As can be seen in FIGS. 6 and 8, the housing of earpiece holder 500 tapers from the central portion to the first end of the housing of earpiece holder 500 in lateral thickness and longitudinal thickness and also tapers from the central portion to the second end of the housing of earpiece holder 500 in lateral thickness and longitude thickness. It is noted that that terms “lateral” and “longitudinal” are relative terms in this context and simply refer to two dimensions which are perpendicular to each other, such as the height and the width. However, in alternative embodiments, the housing of earpiece holder 500 may not taper, may taper to only one end in both lateral and longitudinal thickness, or may taper to both ends in only one dimension (i.e. lateral or longitudinal thickness).

A more specific description of the longitudinal taper and lateral taper of the housing of earpiece holder 500 will now be described.

As can be seen in FIG. 8, the central portion of the housing of earpiece holder 500, including contact patch 81, is between the first end and the second end. As can be seen in FIGS. 8 and 9, earpiece holder 500 tapers from the central portion to both the first end and second end in lateral thickness (i.e. the height or up/down dimension in FIGS. 8 and 9). As can be seen in FIG. 6, earpiece holder 500 tapers from the central portion to both the first end and second end in longitudinal thickness (i.e. the width or right/left dimension in FIG. 6). As can additionally be seen in FIG. 8, the taper from the central portion to the first end in lateral thickness (i.e. the taper in height from the central portion to the right end in FIG. 8) is more gradual than the taper from the central portion to the second end in lateral thickness (i.e. the taper in height from the central portion to the left end in FIG. 8). As can additionally be seen in FIG. 6, the taper from the central portion to the first end in longitudinal thickness (i.e. the taper in width from the central portion to the bottom end in FIG. 6) is more gradual than the taper from the central portion to the second end in longitudinal thickness (i.e. the taper in width from the central portion to the top end in FIG. 8).

As can additionally be seen in FIG. 8, the taper from the central portion of the housing of earpiece holder 500 to the first end in lateral thickness (i.e. the taper in height in FIG. 8) is longitudinally symmetrical (i.e. the taper in height is symmetrical about an axis running left to right, in that the taper on the top side of the housing is the same as the taper on the bottom side of the housing). Similarly, as can be seen in FIG. 8, the taper from the central portion of the housing of earpiece holder 500 to the second end in lateral thickness (i.e. the taper in height in FIG. 8) is longitudinally symmetrical (i.e. the taper in height is symmetrical about an axis running left to right, in that the taper on the top side of the housing is the same as the taper on the bottom side of the housing. As can be seen in the figures, the longitudinal taper from the central portion to the first end and the longitudinal taper from the central portion to the second are arcuate tapers (i.e. in the shape of an arc). Similarly, as can be seen in the figures, the lateral taper from the central portion to the first end and the lateral taper from the central portion to the second end are arcuate tapers (i.e. in the shape of an arc).

As can additionally be seen in FIG. 6, the taper from the central portion of the housing of earpiece holder 500 to the first end in longitudinal thickness (i.e. the taper in width in FIG. 6) is laterally symmetrical (i.e. the taper in width is symmetrical about an axis running up to down, in that the taper on the left side of the housing is the same as the taper on the right side of the housing). Similarly, as can be seen in FIG. 6, the taper from the central portion of the housing of earpiece holder 500 to the second end in longitudinal thickness (i.e. the taper in width in FIG. 6) is laterally symmetrical (i.e. the taper in width is symmetrical about an axis running up to down, in that the taper on the left side of the housing is the same as the taper on the right side of the housing).

The almond shape of earpiece holder 500 not only provides the aforementioned rocking ability, but also provides a distinctive and desirable appearance to the user.

A more specific description of the longitudinal taper and lateral taper of the housing of earpiece holder 500 will now be described.

The almond shape of earpiece 600 will now be described in more detail.

As can be seen in FIGS. 6 and 8, the housing (sometimes referred to herein as a body) of earpiece 600 has a central portion, of which the third portion of the earpiece body (i.e. the portion of the earpiece body about which earpiece 600 pivots on the fulcrum of earpiece holder 500) is a part thereof. The housing of earpiece 600 has a first end which is the right most part of earpiece 600 in FIG. 8 and the bottom most portion of earpiece 600 in FIG. 6. The housing of earpiece 600 has a second end which is the left most part of earpiece 600 in FIG. 8 and the topmost portion of earpiece 600 in FIG. 6. As can be seen in FIGS. 6 and 8, the housing of earpiece 600 tapers from the central portion to the first end of the housing of earpiece 600 in lateral thickness and longitudinal thickness and also tapers from the central portion to the second end of the housing of earpiece 600 in lateral thickness and longitude thickness. It is noted that the terms “lateral” and “longitudinal” are relative terms in this context and simply refer to two dimensions which are perpendicular to each other. However, in alternative embodiments, the housing of earpiece 600 may not taper, may taper to only one end in both lateral and longitudinal thickness, or may taper to both ends in only one dimension (i.e. lateral or longitudinal thickness).

As can be seen in FIG. 8, the central portion of the housing of earpiece 600 is between the first end (i.e. the right most end of earpiece 600 in FIG. 8) and the second end (i.e. the left most end of earpiece 600 in FIG. 8). As can be seen in FIGS. 8 and 9, earpiece 600 tapers from the central portion to both the first end and second end in lateral thickness (i.e. the height or up/down dimension in FIGS. 8 and 9). As can be seen in FIG. 6, earpiece 600 tapers from the central portion to both the first end and second end in longitudinal thickness (i.e. the width or right/left dimension in FIG. 6). As can additionally be seen in FIG. 8, the taper from the central portion to the first end in lateral thickness (i.e. the taper in height from the central portion to the right end in FIG. 8) is more gradual than the taper from the central portion to the second end in lateral thickness (i.e. the taper in height from the central portion to the left end in FIG. 8). As can additionally be seen in FIG. 6, the taper from the central portion to the first end in longitudinal thickness (i.e. the taper in width from the central portion to the bottom end in FIG. 6) is more gradual than the taper from the central portion to the second end in longitudinal thickness (i.e. the taper in width from the central portion to the top end in FIG. 8).

As can additionally be seen in FIG. 8, the taper from the central portion of the housing of earpiece 600 to the first end in lateral thickness (i.e. the taper in height in FIG. 8) is longitudinally symmetrical (i.e. the taper in height is symmetrical about an axis running left to right, in that the taper on the top side of the housing is the same as the taper on the bottom side of the housing). Similarly, as can be seen in FIG. 8, the taper from the central portion of the housing of earpiece 600 to the second end in lateral thickness (i.e. the taper in height in FIG. 8) is longitudinally symmetrical (i.e. the taper in height is symmetrical about an axis running left to right, in that the taper on the top side of the housing is the same as the taper on the bottom side of the housing. As can be seen in the figures, the longitudinal taper from the central portion to the first end and the longitudinal taper from the central portion to the second end are arcuate tapers (i.e. in the shape of an arc). Similarly, as can be seen in the figures, the lateral taper from the central portion to the first end and the lateral taper from the central portion to the second end are arcuate tapers (i.e. in the shape of an arc).

As can additionally be seen in FIG. 6, the taper from the central portion of the housing of earpiece 600 to the first end in longitudinal thickness (i.e. the taper in width in FIG. 6) is laterally symmetrical (i.e. the taper in width is symmetrical about an axis running up to down, in that the taper on the left side of the housing is the same as the taper on the right side of the housing). Similarly, as can be seen in FIG. 6, the taper from the central portion of the housing of earpiece 600 to the second end in longitudinal thickness (i.e. the taper in width in FIG. 6) is laterally symmetrical (i.e. the taper in width is symmetrical about an axis running up to down, in that the taper on the left side of the housing is the same as the taper on the right side of the housing).

The almond shape of earpiece 600 provides a distinctive and desirable appearance to the user. Additionally, when paired with the almond shape of earpiece holder 500, the system provides an earpiece/earpiece holder pair that are similar in shape and geometrically complementary to each other in a visual and tactile manner.

Additional details of earpiece holder 500 will now be described.

Earpiece holder 500 has a plurality of electronic and structural components which provide various functions. It is noted that these are exemplary components and the present technology contemplates embodiments with and without such components, or with any one or any combination of such components.

Earpiece holder 500 has clip 41. Clip 41 is configured for connection to lanyard 79 or other user-attachment device, such as a chain or necklace. As shown in the figures clip 41 is a spring clip. However, in alternative embodiments, clip 41 and/or lanyard 79 are configured differently or omitted.

Earpiece holder 500 has clip 45. Clip 45 is configured for connection to clothing, chain, or lanyard. As shown in the figures clasp 41 is a spring clip. However, in alternative embodiments, clip 41 is configured differently or omitted.

Earpiece holder 500 has wireform mounting pins 43 for mounting clips 41 and 45 to the housing of earpiece holder 500. However, in alternative embodiments, the mounting pins 43 are configured differently or omitted.

Earpiece holder 500 has a contact patch 81 that is anti-friction and anti-wear. Contact patch may be configured to provide such anti-friction and anti-wear, for example, by selecting durable materials as the contact patch such as plastic or metal.. However, in alternative embodiments, contact patch 81 is not configured for anti-friction and anti-wear.

Earpiece holder 500 has a housing. The housing of earpiece holder 500 is constructed as a two-part shell which snap together to form the earpiece body. Specifically the housing has main body 63 and back cover 65. Main body 63 has female snap connectors 69 and top back cover 65 has male snap connectors 71. Male snap connectors 71 and female snap connectors 69 are configured to snap together to secure main body 63 to back cover 65. However, in alternative embodiments, the housing body of earpiece holder 500 may be configured in another manner. Earpiece holder 500 has back cover mounts 73 which provide a stable mounting surface for back cover 65. Earpiece holder 500 has wireform clothes/chain/lanyard clip mounting pin holes 75 which accept wireform mounting pins 43. Wireform clothes/chain/lanyard clip mounting pin holes 75 are provided in cover mounts 73, which provide a strong basis of support for wireform mounting pins 43. Earpiece holder 500 has rear cover release notch 77 which provides an insertion point for a pry tool in order to release main body 63 from back cover 65. However, in alternative embodiments, the housing of earpiece holder 500 may be configured differently and/or may omit any one or any combination of the aforementioned components.

Earpiece holder 500 has a plurality of electronic components that perform various functions. In general, the electronic components are powered by battery 49 and/or controlled by the controller of earpiece holder 500. Additional details of such electronic components will now be described.

Earpiece holder 500 has proximity sensor 1007 for detecting the presence of earpiece 600. Earpiece holder 500 has a controller configured to use proximity sensor 1007 to detect when the earpiece 600 is stowed within the earpiece holder 500. The controller may be configured to determine whether the earpiece 600 is stowed and then perform one or more steps of controlling the earpiece holder 500 based on the determination. For example, the one or more steps of controlling may comprise turning on or off functions, such as turning on a charging circuit based a determination that the earpiece 600 is stowed.

In additional or alternative embodiments, earpiece holder 500 may have any detection circuit configured to detect a change in position of the earpiece relative to the earpiece holder. The detection circuit may comprise at least one sensor that detects a change in position of the earpiece relative to the earpiece holder. For example, the sensor may be proximity sensor 1007, or may be a sensor of transfer of energy from earpiece holder 500 to earpiece 600 through the use of charging electrical conductors 1009, 13 or inductive charging coils (e.g. detection of whether charging of the earpiece 600 from earpiece holder 500 has started or stopped), or may be a sensor of whether a mechanical switch 23 has been activated or deactivated. The detection circuit may further include instructions (e.g. stored on memory of the earpiece holder) that cause a controller of the earpiece holder 500 to execute a function of the system responsive to said detection of the change in position. For example, the instructions can comprise instructions for performing at least one step of control of an electronic component of earpiece holder 500 responsive to said detection of a change in position of the earpiece 600 relative to the earpiece holder 500. Examples of such control of electronic components are taught herein. As an alternative to using instructions stored on memory of the earpiece holder, the detection circuit may be an analog circuit that causes an electronic component of the earpiece holder to activate or deactivate (e.g. activation of a light) based on analog switching induced by the sensory of position.

Earpiece holder 500 has mechanical switch 23 disposed about the earpiece body support 1004 such that the first portion of earpiece 600 contacts and switches the switch when the first portion reaches the first position. Mechanical switch 23 is configured as a push button switch activated upon contact from the earpiece 600. Mechanical switch 23 may be an analog switch, e.g. cutting and supplying power to another component, or a digital switch from which a controller of the earpiece holder receives a signal indicative of the switch state. The controller may be configured to determine whether the earpiece 600 is in the second position, or whether earpiece 600 has just reached or departed from the second position, and then perform one or more steps of controlling one or more electronic components of the earpiece holder 500 based on the determination. For example, the one or more steps of controlling may be any controller function(s) or step(s) taught herein.

Earpiece holder 500 has control button 15, control button 17, control button 33, and control button 35. The control buttons are configured for operation by the user to control functions of earpiece holder 500. Control button 15 may be configured to perform any controller function or step taught herein. Control button 17 may be configured to perform any controller function or step taught herein. Control button 33 may perform any controller function or step taught herein. Control button 35 may be configured to perform any controller function or step taught herein. However, in alternative embodiments, any one or any combination of the control buttons are omitted or operate different functions.

Earpiece holder 500 has USB-C charge port 19 as a source of power. The charge port is configured to provide power to earpiece holder 500, such as to charge its battery 49 or provide power to the electronic components of earpiece holder 500. However, in alternative embodiments, earpiece holder 500 may have a charging port other than a USB-C charging port, may omit a charging port, and/or may be configured to charge by a different mechanism (e.g. inductive charging).

Earpiece holder 500 has secondary inductive charging circuit secondary coil 47 as a power source. The secondary inductive charging circuit secondary coil 47 is configured to act as receiver coil and provide power to earpiece holder 500, such as to charge its battery 49. Specifically, secondary inductive charging circuit secondary coil 47 is configured to receive power from a primary inductive charging circuit secondary coil of an external inductive charging device (not shown) when earpiece holder 500 is placed in sufficient proximity thereto. However, in alternative embodiments, earpiece holder 500 may omit a secondary coil, and/or may be configured to charge by a different mechanism.

Earpiece holder 500 has battery 49. Battery 49 may be used to power components of the Earpiece holder 500 and/or used as a power source to charge Earpiece 600. Battery 49 is configured to be recharged via the holder's sources of power described above.

Earpiece holder 500 has microphone 21 and 39. Microphone 21 is configured for receiving voice input from a user. Microphone 39 is configured for receiving voice input from a user. However, in alternative embodiments, microphone 21 and/or microphone 39 is omitted or configured differently. For example, earpiece holder 500 may be configured to receive voice input from the user by the microphone(s) in any manner, for example, to make voice calls and/or receive voice-prompts for making internet queries or providing voice-based response responses.

Earpiece holder 500 has speaker 31. The controller of earpiece holder 500 is configured to control speaker 31 to produce sound, e.g. for voice calls and/or to provide audio feedback to the user. However, in alternative embodiments, speaker 31 is omitted or configured differently.

Earpiece holder 500 has light 37. A controller of earpiece holder 500 is configured to control light 37. Light 37 may be configured as an RGB LED flash, flashlight, or notification indicator. However, in alternative embodiments, light 37 is omitted or configured differently.

Earpiece holder 500 has diode laser pointer 83. Laser pointer is configured for use as a pointer and/or distance measurement (i.e. as a range finder). However, in alternative embodiments, laser pointer 83 is omitted or configured differently.

Earpiece holder 500 has camera 1003. Camera 1003 is configured for use during video calls or to record the space around the earpiece holder. However, in alternative embodiments, camera 1003 is omitted.

Earpiece holder 500 has a circuit board connecting each of the electronic components described above and below to battery 49 and/or controller. Specifically, the circuit board is configured as PCB 51 (printed circuit board). More specifically, the electronic components are powered and networked through a series of nodes (49, 85, 87, 89, 91, 93, 95, 97, 99, 101, 103, 105, 107, 109, 111, 113, 115, 117, 119, 121, 123, 125) on the PCB 51, which will now be described in more detailed. However, it is noted that, in alternative embodiments, Earpiece holder 500 may omit any one or any combination of such electronic components and the electronic components may be powered in a different manner and/or networked in a different manner. Further, as an alternative to a PCB, earpiece holder 500 may have a different structure for operably connecting the electronic components to the controller and/or batter.

PCB 51 is configured in the following manner. In general, each node provides an electrical connection(s) to the battery for powering the electronic component and/or an electrical connection(s) to the controller for control of the electronic component.

Earpiece holder 500 has microphone node 85 for connecting microphone 21.

Earpiece holder 500 has light node 87 for connecting light 37.

Earpiece holder 500 has control button node 89 for connecting control button 35.

Earpiece holder 500 has control button node 91 for connecting control button 33.

Earpiece holder 500 has speaker node 93 for connecting speaker 31.

Earpiece holder 500 has camera node 95 for connecting camera 1003.

Earpiece holder 500 has inertial measurement unit (IMU) node 97 for connecting an IMU of earpiece holder 500. The IMU has, for example, three accelerometers and three gyroscopes.

Earpiece holder 500 has diode laser node 99 for connecting diode laser pointer 83.

Earpiece holder 500 has radio antenna node 101 for connecting a radio antenna of earpiece holder 500.

Earpiece holder 500 has inductive charge controller node 103 for connecting circuit secondary coil 47.

Earpiece holder 500 has proximity sensor node 105 for connecting proximity sensor 1007.

Earpiece holder 500 has button 3 node 107 for connecting a button.

Earpiece holder 500 has memory chip node 109 for connecting a memory chip of Earpiece holder 500.

Earpiece holder 500 has earpiece charge controller node 111 for connecting the charging components.

Earpiece holder 500 has CPU node 113 for connecting the controller of Earpiece holder 500.

Earpiece holder 500 has control button node 115 for connecting a control button.

Earpiece holder 500 has cellular/WIFI/GPS transceiver node 117 for connecting a cellular transceiver, WIFI transceiver, and GPS transceiver.

Earpiece holder 500 has USB-C charge controller node 119 for connecting a USB-C charge controller which controls charging through USB-C charge port 19.

Earpiece holder 500 has Bluetooth transceiver node 121 for connecting a Bluetooth transceiver of Earpiece holder 500.

Earpiece holder 500 has SIM card slot/reader node 123 for connecting a SIM card slot/reader.

Earpiece holder 500 has microphone node 125 for connecting microphone 39.

Additional details of earpiece 600 will now be described.

Earpiece 600 has a plurality of electronic and structural components which provide various functions. It is noted that these are exemplary components and the present technology contemplates embodiments with and without such components, or with any one or any combination of such components.

Earpiece 600 has press point area 46. Press point area 46 is an area which can be pressed by the user to pivot earpiece 600 from the first position to the second position.

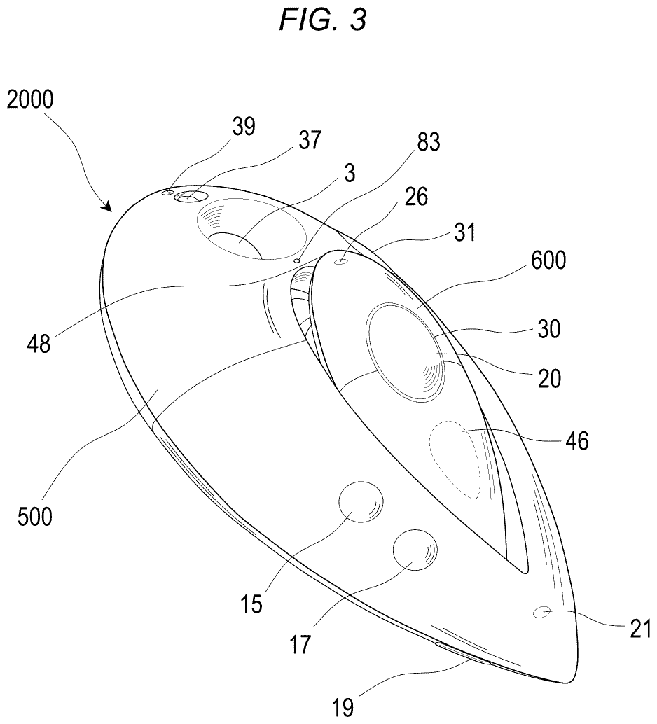

Earpiece 600 has lifting edge 48, which is labeled in FIG. 3. Lifting edge provides a contact point for the user to lift and remove the earpiece 600 from earpiece holder 500 when earpiece 600 is in the second position. Specifically, lifting edge 48 protrudes from cavity 1005 when earpiece 600 is in the second position, exposing the contact point to the user such that the user can use a finger picking position (or “come here” motion) to lift earpiece 600 from earpiece holder 500.

Earpiece 600 has earpiece neck 22 which connects the ear interface of earpiece 600 to the earpiece body of earpiece 600. Neck 22 is provided with a length that distances the ear interface optimally from the earpiece body such that the earpiece body is outside of the user's ear when the ear interface is in (or partially in) the ear.

As an ear interface 2004, earpiece 600 has an ear gel 2008 and ear gel nubs 2014. Together, the ear gel and ear gel nubs provide a snug fit in the ear of a user. However, in alternative embodiments, the ear interface may omit the ear gel or nubs and may be configured in any other manner for interfacing with a user's ear.

The earpiece body of earpiece 600 is constructed as a two-part shell which snap together to form the earpiece body. Specifically, earpiece body has main body 38 and top cover 40. Main body 38 has male snap connectors 44 and top cover 40 has top cover female snap connectors 42. Male snap connectors 44 and top cover female snap connectors 42 are configured to snap together to secure main body 38 to top cover 40. However, in alternative embodiments, the earpiece body of earpiece 600 may be configured in another manner.

Earpiece 600 has a plurality of electronic components that perform various functions. In general, the electronic components are powered by battery 44 and/or controlled by the controller of earpiece 600. Additional details of such electronic components will now be described.

Earpiece 600 has touch sensor 20. Touch sensor 20 is a capacitive touch sensor. A controller of earpiece 600 is configured to receive user input from touch sensor 20 and perform functions responsive to the user input. The controller may be configured to perform gesture-based control of the functions in which the controller determines that a s specified gesture from a plurality of predetermined gestures has been made by the user using touch sensor 20, and perform a respective function corresponding to the specified gesture. However, in alternative embodiments, earpiece 600 may omit touch sensor 20 or touch sensor 20 may be configured differently.

Earpiece 600 has microphone 10 and microphone 26. Microphone 10 is configured for receiving the voice of the user during calls. Microphone 26 is configured for receiving audio input for another function, such as receiving ambient audio for reference by a noise-cancelling function of the controller. However, in alternative embodiments, the microphones are configured differently and/or one or both of the microphones is omitted.

Earpiece 600 has control button 30. Control button 30 is configured as a mechanical control button. Control button 30 is configured to operate as an answer/hangup button. However, in alternative embodiments, control button 30 may be omitted or may be configured in another manner.

Earpiece 600 has speaker 2006 for transmitting audio to the ear of a user.

Earpiece 600 has a circuit board connecting each of the electronic components of earpiece 600 described above and below to battery 24 and/or controller. Specifically, the circuit board is configured as PCB 28 (printed circuit board). More specifically, each of the electronic components are connected to PCB 28. In general, for each electronic component, PCB 28 electrical connection(s) to the battery for powering the electronic component and/or an electrical connection(s) to the controller for control of the electronic component. However, it is noted that, in alternative embodiments, earpiece 600 may omit any one or any combination of such electrical components and the electrical components may be powered in a different manner and/or networked in a different manner. Further, as an alternative to a PCB, earpiece 600 may have a different structure for operably connecting the electronic components to the controller and/or battery.

### Controller-Based Control of Functions

Earpiece holder 500 and earpiece 600 each have an independent controller configured to control functions on the earpiece holder 500 and earpiece 600, respectively. Each of the controllers may be independently configured as follows.

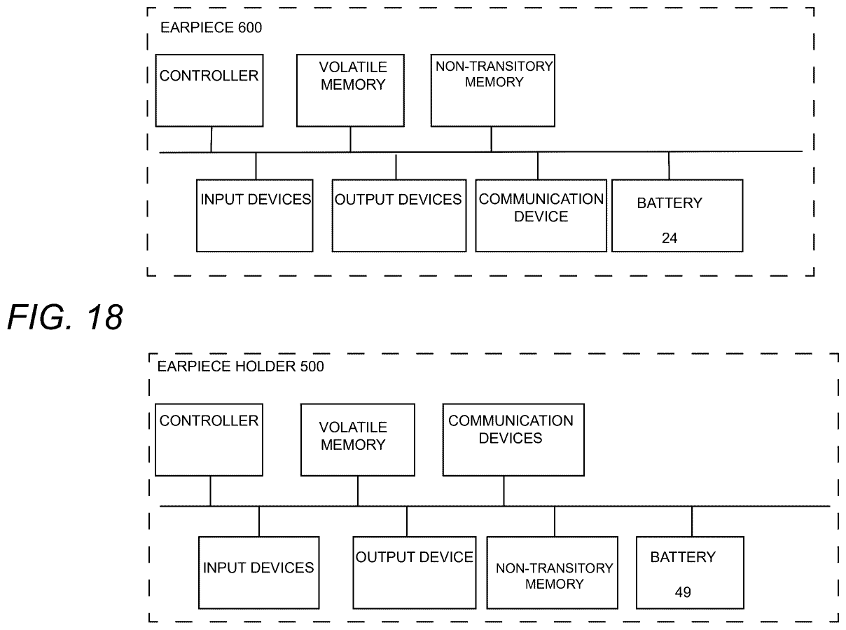

In order to configure the controller to control electronic components of the respective device, earpiece holder 500 and earpiece 600 may, according to some embodiments, implement the architecture shown in FIG. 18. However, it is noted that, in alternative embodiments, the holder 500 and earpiece 600 may omit components shown in FIG. 18 and/or include additional components shown in FIG. FIG. 18.

As shown in FIG. 18, each respective device (i.e. Earpiece holder 500 or earpiece 600) may comprise a controller, a memory (e.g. transitory and/or non-transitory), and a bus, or other structure configured for connecting the controller to the other electronic components of the respective device. The memory may be configured for storing a module(s) comprising instructions. The controller may be configured to read the module(s) stored on the memory and perform functions according to the instructions of the modules. For example, the present technology teaches examples of control steps of performing certain functions by controlling electronic devices on the earpiece or earpiece holder, such as an input device, output device, or both. Examples of such control include cycling through or switching any one or any combination of a discrete setting for audio volume, audio/video playback speed, process acceleration, light source brightness, light source pulse intermittency, light source color, and/or camera zoom level. Instructions for such control steps may be provided on memory which, when read by the controller, causes the controller to perform said functions. Additionally or alternative, such functions may be configured to be dependent (or “responsive to”) the controller making a specified determination, such as the presence of absence a certain state of another function or component. For example, the controller of the earpiece holder may be configured to perform certain functions based on the determination that the earpiece is in a specified position, or has been moved from a specified position to another specified position, as detection by proximity sensor 1007 or connection/disconnection of a charging circuit, the state of which is dependent on the position of the earpiece relative to the earpiece holder. Such responsive steps can be configured by providing instructions, on the memory, of making a determination and then performing a respective function responsive to the determination.

The controller may be an analog or digital controller. The controller may be a microprocessor, central processing unit (CPU), a graphics processing unit (GPU), an analog circuitry, Field Programmable Analog Array, a Field-programmable gate array (FPGA), complex programmable logic device (CPLD), programmable array logic (PAL) device, an application specific integrated circuit (ASIC), a digital signal processor, a reconfigurable logic device, or a special-purpose computing engine.

The controller may be a processor configured to access memory comprised by the respective device. Examples of such processors are well-known in the art and are commonly connected to the memory by a system bus (e.g. on a motherboard). The processor may be any processor that can read instructions, e.g. present in a module stored on memory, and control the respective device according to the instructions.

As shown in FIG. 18, each respective device (i.e. earpiece holder 500 and/or earpiece 600) may further comprise a communication device for connecting with each other and/or one or more other devices such as another computing device. The communications device may include a wired communication device (e.g. LAN device) or wireless communication device (e.g. devices with any combination of Bluetooth, Wi-Fi, NFC, cellular, satellite or other wireless signaling ability). The communication device may comprise a network access device such as any device configured to transmit data between the respective device and another computing device (e.g. personal computer or other computer) over a network. Examples of network access devices include network adapters, for example, wired adapters such as ethernet adapters and wireless adapters such as Wi-Fi adapters (e.g. 802.11 adapter) and cellular adapters (e.g. GSM, TDMA, CDMA, 3G, 4G, 5G adapters).

As shown in FIG. 18, each respective device may comprise one or more input devices and/or output devices, according to some embodiments. In general, input devices send signals to the controller while output devices receive signals from the controller. However, it is noted that some electronic devices of the earpiece or earpiece holder act as both an input and output device. According to some embodiments, examples of input devices of the earpiece holder include electronic components 1003, 1007, 15, 17, 21, 23, 33, 35, 37, 39, 83, and 85 described herein. According to some embodiments, examples of output devices of the earpiece holder include electronic components 25, 31, 47, 83, 87 described herein. According to some embodiments, examples of input devices of the earpiece include electronic components 10, 20, 26, and 30 described herein. According to some embodiments, examples of output devices of the earpiece include electronic components 2006, and 26 described herein.

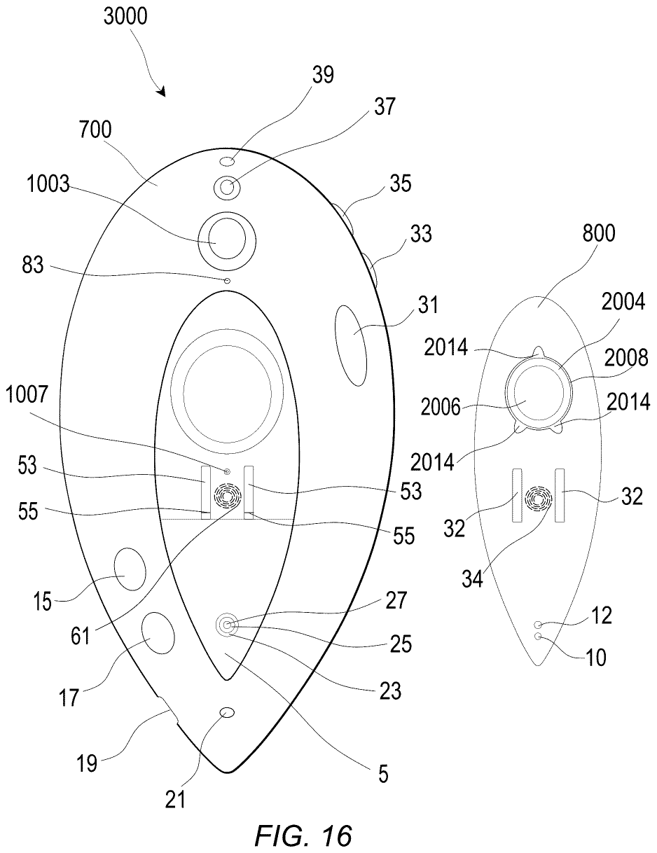

### System 3000/FIG. 16

A system according to one or more embodiments will now be described with reference to the accompanying drawings. In one implementation, the system is system 3000. System 3000 is shown in FIG. 16 and has earpiece holder 700, earpiece 800, releasable fastener 300, releasable fastener 301. System 3000 is the same as system 2000, except that 1) the configuration for charging the earpiece from the earpiece holder is different, 2) the fulcrum of the earpiece holder and respective pivot point of the third portion of the earpiece body are different, and 3) the releasable fastener 301, configured for releasably attaching the second portion of the earpiece body to the earpiece holder, is different. Specifically, regarding the charging configuration, system 3000 has an inductive charging system for charging earpiece 800 from earpiece holder 700, rather than the conductive charging circuit (charging circuit conductors 13, 14, 18, and 1009) of system 2000. Regarding the fulcrum and pivot point, fulcrum 55 of earpiece holder 700 is configured as a discontinuous fulcrum. Regarding releasable fastener 301, configured for releasably attaching the first portion of the earpiece body to the earpiece holder, system 3000 has a pair of interacting discontinuous magnets that form a magnetic clasp. Accordingly, for the sake of brevity, only the differences will be discussed below. Additionally, it is noted that, as system 3000 has specific implementations of the features generally described with respect to system 1000, reference will be made to FIG. 1 when referring to relative positions of earpiece holder 700 and earpiece 800 of system 3000 (e.g. the “first” or “second” position of the earpiece). However, it is noted that, in alternative embodiments, a system, earpiece, or earpiece holder may only have any one or any two of features 1)-3).

System 3000 has an inductive charging circuit configured for charging earpiece 800 from earpiece holder 700.

Earpiece holder 700 has inductive charging circuit primary coil 61 as a second coil. Inductive charging circuit primary coil 61 is electrically connected to battery 49 of earpiece holder 700 such that inductive charging circuit primary coil 61 can receive electrical energy from battery 49 and transmit the energy to secondary coil 34.

Earpiece 800 has inductive charging circuit secondary coil 34 as a receiving coil. Inductive charging circuit secondary coil 34 is electrically connected to battery 24 of earpiece 800 such that battery 24 can receive electrical energy from inductive charging circuit secondary coil 34 and transmit the received energy to battery 24.

Inductive charging circuit primary coil 61 and inductive charging circuit secondary coil 34 are disposed about earpiece holder 700 and earpiece 800 respectively, such that, when earpiece 800 is stowed in earpiece holder 700, inductive charging circuit primary coil 61 and inductive charging circuit secondary coil 34 are operably linked to transfer electric power from inductive charging circuit primary coil 61 to inductive charging circuit secondary coil 34. By this configuration, battery 49 of earpiece holder 700 can charge battery 24 of charge earpiece 800 when earpiece 800 is stowed in earpiece holder 700. More specifically, inductive charging circuit primary coil 61 and inductive charging circuit secondary coil become operably linked at least when earpiece 800 is in the first position shown in FIG. 1C.

Earpiece holder 700 has magnetic fulcrum 55 on which earpiece 800 can pivot about its pivot point. Specifically, earpiece 800 has magnets 32 which provide the pivot point for the earpiece body of earpiece 800 to pivot about magnetic fulcrum 55. Magnetic fulcrum 55 is configured as a discontinuous fulcrum in that it has a pair of magnets spaced apart. Similarly, the pivot point of earpiece 800 is a discontinuous pivot point, provided by a pair of magnets 32 spaced part by the same distance of which the pair of magnets of magnetic fulcrum 55 are spaced such that the pair of magnets 32 and magnetic fulcrum 55 can align with each other to form a functional fulcrum/pivot point combination.

System 3000 has releasable fastener 301 provided by a pair of magnets 53 on earpiece holder 700 and the pair of magnets 32 on earpiece 800. Specifically, the pair of magnets 53 on earpiece holder 700 and the pair of magnets 32 on earpiece 800 are spaced apart by the same distance such the pair of magnets 53 and pair of magnets 32 can align with each other and form a functional magnetic clasp when earpiece 800 is in the first position shown in FIG. 1C.

As shown in FIG. 16, magnetic fulcrum 55 is an edge portion of magnets 53 on earpiece holder 700 such that a single pair of magnets provides both: one of the components of the magnetic clasp of system 3000 and the fulcrum of earpiece holder 700. Similarly, as shown in FIG. 16, the pair of magnets 32 provides both: one of the components of the magnetic clasp of system 3000 and the pivot point of earpiece 800. However, in alternative embodiments, the clasp component of earpiece holder 700 and the fulcrum of earpiece holder 700 may be provided by different bodies, and/or the clasp component of earpiece 800 and the pivot point of earpiece 800 may be provided by different bodies.

As illustrated in FIG. 16, the discontinuous and spaced configuration of magnetic fulcrum 55, pair of magnets 53, and pair of magnets 32 allows inductive charging circuit primary coil 61 and inductive charging circuit secondary coil 34 to be disposed between the spaced apart pairs. Configured in this manner, the magnets of the fulcrum, pivot point, and clasp do not interfere (or interfere less) with the inductive transfer of electrical energy from inductive charging circuit primary coil 61 to inductive charging circuit secondary coil 34.

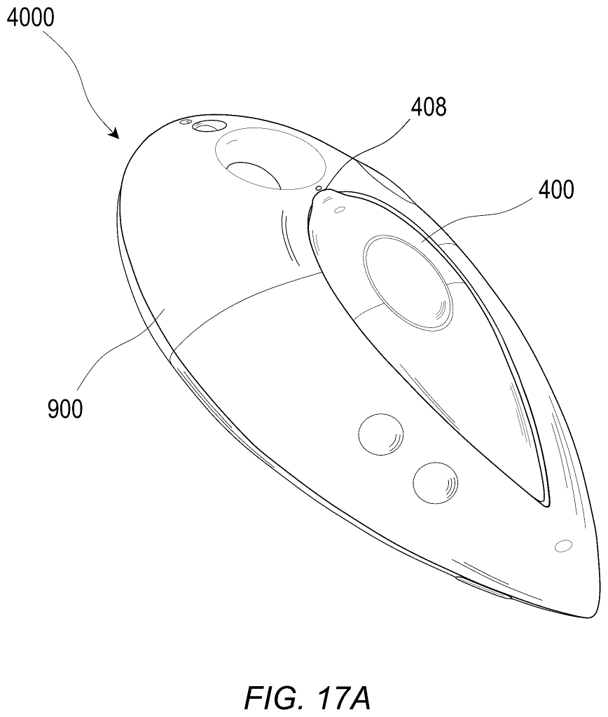

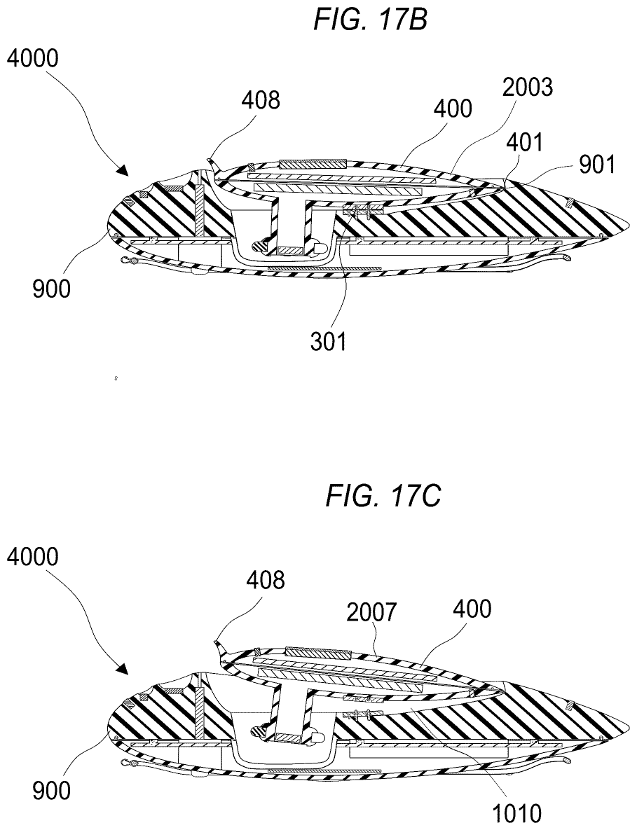

### System 4000/FIG. 17

A system according to one or more embodiments will now be described with reference to the accompanying drawings. In one implementation, the system is system 4000. System 4000 is shown in FIGS. 17A-17C and has earpiece holder 900, earpiece 400, and releasable fastener 301. System 4000 is the same as system 2000, except for the following differences.

System 4000 omits magnetic fulcrum 29 and releasable fastener 300, and the fulcrum cavity 1010 of earpiece holder 900 is configured such that, when earpiece 400 is stowed in earpiece holder 900, the distal end 401 of earpiece 400 contacts pocket 901 of the distal end of fulcrum cavity 1010.

The distal end of fulcrum cavity 1010 is configured as a pocket 901 about which the distal end 401 of earpiece 400 can pivot. In other words, pocket 901 provides a second fulcrum about which earpiece 400 can pivot. Configured in this way, the pivoting of distal end 401 of the earpiece body in pocket 901 of the earpiece holder provides a second class lever. In alternative embodiments, system 4000 comprises a fulcrum other than pocket 901, but which still provides a second class lever when combined with lifting edge 408 or other lifting edge.

Configured as such, lifting of the lifting edge 408 causes the earpiece 400 to pivot about distal end 401 in pocket 901 (i.e. pivoting from the position shown in FIG. 17B to the position shown in FIG. 17C). In order to lift earpiece 400 for such pivoting, the user must apply enough lifting force to release releasable fastener 301. The user may then remove earpiece 400 from earpiece holder 900.

Earpiece 400 has lifting edge 408 configured as a protrusion that extends transversely from the outer surface of the earpiece body of earpiece 400 Lifting edge 408 is disposed on earpiece 400 such that it is engageable by a user's finger when the earpiece body is in the first position shown in FIG. 17B. As shown in FIG. 17B, the first position is a position in which the earpiece 400 is stably stowed in earpiece holder 900.

As shown in FIG. 17B, releasable fastener 301 is configured for releasably attaching a portion of the earpiece body to an earpiece support (i.e. a portion of the earpiece holder which can support the earpiece), when the earpiece body is stowed in a first position. Lifting edge 408 is disposed about the earpiece body such that lifting edge 408 is pluckable, or otherwise graspable, by a user, and lifting of the earpiece body by lifting edge 408 causes the distal end 401 of earpiece body to pivot about the fulcrum (i.e. pocket 901) from the first position shown in FIG. 17B to the second position shown in FIG. 17C.

Lifting edge 408 is disposed near the opposing distal end of earpiece 400, relative to distal end 401. In alternative embodiments, lifting edge 408 may be disposed in any other location such that lifting of the earpiece body by the lifting edge 408 causes the earpiece body to pivot about the pocket 901, for example, pivoting from the first position shown in FIG. 17B to the second position shown in FIG. 17C.

In the example shown in FIG. 17, lifting edge 408 is a protrusion extending at about a 90-degree angle from the outer surface of the earpiece body. However, in alternative embodiments, the protrusion may extend from the outer surface of the earpiece body at any other transverse angle (e.g. an acute angle) such that a user's finger can pluck or otherwise grasp the lifting edge 408 using a picking (“come here” motion of the finger to lift the earpiece.

Lifting edge 408 is part of a second portion of the earpiece body. Releasable fastener 301 is configured for releasably attaching a first portion of the earpiece body to an earpiece body support of earpiece holder 900 (i.e. when the earpiece body is in the first position shown in FIG. 17B). Distal end 401 (i.e. the pivot point) is a part of a third portion of the earpiece body. In the example shown in FIG. 17, the second portion is the left most portion of the earpiece body, first second portion is the middle portion of the earpiece body and the third portion is the right most portion earpiece body. However, in alternative embodiments, earpiece 400 may be configured in any manner such that the first portion is between the second portion and the third portion. Configured in this way, the combination of distal end 401 of the earpiece body and pocket 901 of the earpiece holder provides a second class lever when the user's force is applied to lifting edge 408 to cause pivoting.

As described with respect to system 1000, the releasable fastener 301 of system 4000 is configured for releasably attaching a portion of the earpiece body of earpiece 400 to an earpiece body support of earpiece holder 900 in the first position shown in FIG. 17B. Specifically, releasable fastener 301 has a pair of interacting couplers, wherein one of the couplers is fixed to earpiece holder 900 and the other coupler is fixed to earpiece 400. At least one of the couplers is a first magnet and the other coupler is either a second magnet that is attracted to the first magnet or material (e.g. iron) that is attracted to the first magnet. The interacting couplers of releasable fastener 301 are respectively disposed such that, as earpiece 400 is pivoted about the fulcrum (pocket 901) from the first position shown in FIG. 17B to the second position shown in FIG. 17C, the distance between the interacting couplers of releasable fastener 301 increase in distance, and the magnetic attractive force between the interacting couplers decreases. Conversely, the attractive magnetic force of the interacting couplers is configured such that, after earpiece 400 is pivoted about the fulcrum (pocket 901) by the force of user (i.e. user's finger) from the second position shown in FIG. 17C towards the first position shown in FIG. 17B in which and the distance between the interactive couplers of releasable fastener 301 has been decreased, there is enough magnetic attractive force between the spaced apart interacting couplers of releasable fastener 301 to bias earpiece 400 to return to the first (stowed) position shown in FIG. 17B (e.g. in the absence of additional force by the user to continue moving the earpiece towards the first position). Additionally, it is noted that the magnetic strength of releasable fastener 301 may be configured such that, if the user releases grasp from lifting edge 408 when earpiece 400 is in the second position shown in FIG. 17C, earpiece 400 returns to the first (stowed) position shown in FIG. 17B due to the attractive force of the interacting couplers of releasable fastener 301.

An interacting coupler of releasable fastener 301 is provided about a first portion of the earpiece body of earpiece 400. Lifting edge 408 is provided about a second portion of the earpiece body of earpiece 400. Distal end 401 is provided about a third portion of the earpiece body of earpiece 400. As shown in FIG. 17, the first portion is between the second portion and third portion. Additionally, the third portion is positioned about an end of the earpiece body. However, in alternative embodiments, the components may be disposed in different locations. Additionally or alternatively, rather than distal end 401, the third portion of the earpiece body may comprise any structure configured to pivot about a fulcrum such as pocket 901.

As shown in FIG. 17, the second portion of the earpiece body (which comprises the lifting edge 408) is positioned relative to the third portion of the earpiece body (which comprises the distal end 401) such that, when the earpiece body is in the second position shown in FIG. 17C, the third portion of the earpiece body is supported by the earpiece holder, and the second portion of the earpiece body is raised from the cavity, relative to the position of the second portion of the earpiece body when the earpiece body is in the first position shown in FIG. 17B.

As shown in FIG. 17, pocket 901 of earpiece holder 900 provides a second earpiece body support for supporting the earpiece body of earpiece 400 such that that the second earpiece body support is engaged with the distal end 401 of the of the earpiece body at least when the earpiece body is in the second position shown in FIG. 17C. It is noted that, in the second position shown in FIG. 17, pocket 901 supports the earpiece body together with the user's finger on lifting edge 408. Moreover, the pocket 901 of earpiece holder 900 is positioned such that the pocket 901 engaged with the distal end 401 of the earpiece body when the earpiece body is in the first (i.e. stowed) position shown in FIG. 17B. In alternative embodiments, the earpiece holder may comprise any second earpiece body support positioned such that the second earpiece body support is engaged with the third portion of the earpiece body at least when the earpiece body is in the second position and/or the second earpiece body support is positioned such that the second earpiece body support is engaged with the third portion of the earpiece body when the earpiece body is in the first position.

Pocket 901 is a portion of the cavity wall of earpiece holder that provides a concave surface engageable by distal end 401 of the earpiece body of earpiece 400. In alternative embodiments, earpiece holder 900 may be configured in any manner that provides a concave surface engageable by a protrusion of the earpiece for pivoting of the earpiece body about the concave surface by the protrusion. For example, although the protrusion may be distal end 401, it may be alternatively configured as a portion of the earpiece body other than the distal end.

In the example shown in FIG. 17, the system does not include releasable fastener 300. However, in alternative embodiments, system 4000 may include releasable fastener 300.

### Example Uses and Configurations

The following description provides examples of features and uses that may be implemented in a system, earpiece holder, earpiece, or method of the present technology, according to some embodiments.

In the particular configuration shown in the figures, system 2000, system 3000, and system 4000 are each configured as wearable device and allows a user to readily and optimally perform a number of tasks which would otherwise require the use of a smartphone and/or a number of other discrete gadgets. These systems provide a user with utmost convenience in a form of minimal mass and volume, a fraction that of the average smartphone.

Each of systems 2000, system 3000, and system 4000 provides a wearable wireless earpiece holder and its compatible earpiece. Features of the systems include the structural features by which the earpiece holder detachably stows, charges and deploys earpiece, such that the earpiece is readily available for a user to promptly answer incoming calls, and the earpiece's battery 24 may be continuously recharged by the earpiece holder while stowed.

Releasable fastener 301, which, in the particular embodiment of system 2000, is in the form of a magnetic clasp provided by magnets 11 and 16, and in the particular embodiment of system 3000, is in the form of a magnetic clasp provided by magnets 53 and 32, allows the earpiece to securely stow and recharge its battery 24 when flushly housed within the prevailing contours of the earpiece holder which prevents accidental dislodging of the earpiece while allowing a user to quickly and reliably deploy the earpiece. For example, a user may deploy earpiece by applying pressure in proximity to the press point 46 of the earpiece, thus pivoting the earpiece upon the magnetic fulcrum 29 or magnetic fulcrum 55 of the earpiece holder into (or further into) cavity 1005 of earpiece holder which reveals the readily graspable lifting edge 48 of the earpiece, allowing quick and reliable deployment of the earpiece. For example, FIG. 2 shows a perspective view of system 2000 in which earpiece 600 flushly is stowed within the earpiece holder 500 (sometimes referred to herein as the ‘first’ position). FIG. 3 shows a perspective view of system 2000 in which earpiece 600 is fully pivoted upon the fulcrum 29 and ready to deploy (sometimes referred to herein as the ‘second’ position). FIG. 9 shows an elevation sectional view of system 2000 in the first position, flushly stowed within earpiece holder 500. FIG. 11 shows an elevation sectional view of earpiece 600 in the second position, with earpiece 600 fully pivoted and ready to deploy. System 3000 has the same functionalities and advantages. Additionally, according to some embodiments, system 1000 provides such functionalities and advantages.

In various configurations of a system taught herein, battery 24 of an earpiece may be recharged by a number of configurations while it is stowed in a respective earpiece holder.

In the configuration illustrated by system 2000, when earpiece 600 is stowed in the earpiece holder 500, magnet 11 of earpiece holder 500 attracts the corresponding magnet 16 of earpiece 600, such that charging circuit conductors 14, 18 of earpiece 600 reliably align and connect with sprung charging circuit conductors 1009, 13 of earpiece holder 500 such that a charging circuit is completed and battery 24 of earpiece 600 can be continuously recharged from battery 49 of earpiece holder 500, thereby acting as an reserve, until battery 24 is fully charged, or until earpiece 600 is deployed. As detailed above, FIG. 9 shows an elevation sectional view of system 2000 while the earpiece 600 while stowed within earpiece holder 500 and charging.

In the configuration illustrated by system 3000, an alternative mechanism by which the earpiece 800 can recharge while stowed within the earpiece holder 700 is shown in FIG. 16, wherein magnets 32 of earpiece 800 align with the corresponding pair magnets 53 of earpiece holder 700 to form a functional magnetic clasp, such that the secondary inductive coil 34 of the earpiece 800 aligns in close proximity with the primary inductive coil 61 of earpiece holder 700 to complete an inductive charging circuit while the earpiece 800 is attached to, and stowed within earpiece holder 700. The inductive charging circuit can be powered or depowered on the earpiece holder's primary side of the inductive charging circuit by means of input from the proximity sensor 1007 of earpiece holder 700, which reliably detects when the earpiece 800 is stowed within the earpiece holder 700.

Each of system 1000, system 1001, system 2000, and system 3000 have the following technical features, according to some embodiments. While stowed within the holder of the system, the respective earpiece may pivot upon the holder's fulcrum (fulcrum 1002, magnetic fulcrum 29 or magnetic fulcrum 55) between two extremes, one being the flushly mounted charging position represented in FIG. 1A, FIG. 1C, FIG. 2, and FIG. 9 (sometimes referred to herein as the ‘first position’), the other extreme represented by the fully pivoted position seen in FIG. 1B, FIG. 1E, FIG. 3, and FIG. 11 (sometimes referred to herein as the ‘second position’). When the earpiece is fully pivoted by pressing on the earpiece's press point 46 to cause the earpiece to pivot to the second position, the earpiece can be removed from the holder by the user grasping the earpiece's lifting edge 48.

It is noted, however, that, in alternative embodiments, the systems may omit any of the aforementioned features.

According to some embodiments, any of the systems taught herein may have or may be modified to have any one or any combination of the following of the following features.

According to some embodiments, the system is configured such that, if the pressure on earpiece's press point 46 is released, the earpiece will automatically pivot and return to the first position due to the proximity and mutual attraction of the magnets (11 and 16, or 32 and 53) that form the magnetic clasp of the second releasable fastener. As a first example, the system may omit the first releasable fastener (e.g. omit magnets 12, 25, 27) such that the system does not have a fastener for maintaining the earpiece in the second position. As a second example, the system may have the first releasable fastener, but the first releasable fastener is configured to be released, after a period of time, e.g. by configuring the releasable fastener with an electromagnet 25 that automatically turns off automatically turns off after a period of time following pivoting of the earpiece to the second position. To illustrate this second example, the earpiece holder may be provided with a permanent magnet 27, an electromagnet 25, and a mechanical switch 23, disposed within the holder's cavity 1005, allowing the earpiece to be maintained in the second position for easier removal of the earpiece from the holder. The permanent magnet 27 of releasable fastener 300 may be configured with a sufficient strength to maintain the earpiece in the second position by counteracting the mutual attraction of the corresponding magnetic clasps (e.g. provided by 11 and 16, or 53 and 32) of releasable fastener 301. To return the earpiece to the flush or first position, a user would push on the upper portion of the earpiece 600 near the edge 48, such that mutual attraction of the corresponding magnetic clasps (e.g. provided by 11 and 16, or 53 and 32) overcomes the mutual attraction of magnets of the releasable fastener 300 (12, 27) within the cavity 1005. Additionally, the holder's permanent magnet 27 may be of a lesser sufficient strength to maintain the earpiece in the fully pivoted or second position when augmented with an electromagnet 25 of sufficient strength. The circuit of electromagnet 25 may be configured to be powered for a specified duration of time (e.g. controlled by a controller) in the fully pivoted position, whereafter the electromagnet 25 circuit switches off, allowing the earpiece to automatically return to the flush mounted charging position. Powering of the electromagnet 25 circuit may be controlled by a controller, responsive to input from the proximity sensor 1007 and/or disconnection of the conductive or inductive charging circuit between the holder and earpiece. In addition to or as an alternative to the use of time duration-based control of the electromagnet, the holder may be provided with a mechanical switch 23 disposed within the cavity 1005, which may connect and disconnect any circuit(s) within the holder and/or earpiece, such as a power circuit which powers electromagnet 25.

According to some embodiments, the system is configured such that the earpiece can be partially pivoted upon the holder's magnetic fulcrum (e.g. 29 or 55) to effect alternating or progressive switching of any circuit by means of a proximity sensor's (1007) sensing of the earpiece's proximity and subsequent input to software control of other circuits by a controller (e.g. CPU) of the earpiece holder or otherwise directly influencing any integral component of the earpiece holder and/or earpiece or any wirelessly connected peripheral device. For example, the system may be configured with a controller and control instructions (e.g. program stored on non-transitory recording medium) that causes the controller to, responsive to determining that the earpiece is pivoting or has been pivoted about the fulcrum (e.g. 29), perform steps of controlling one or more functions of the earpiece holder, earpiece, or system, such as cycling through or switching any one or any combination of a discrete setting for audio volume, audio/video playback speed, process acceleration, light source brightness, light source pulse intermittency, light source color, and/or camera zoom level. For example, the system can be configured such that the manual partial pivoting, or rocking of the earpiece can proceed nearly to the degree illustrated in FIG. 10, and the earpiece will automatically return to the flush charging position of FIG. 9 upon release.

According to some embodiments, the system is configured such that a holder's camera 1003, light 37 (e.g. RGB LED flashlight), and laser pointer 83 all are optimally positioned for quick access and use when the holder is worn on an article of clothing, such as by clothes clip 45, or worn as a pendant attached to a lanyard 79 or necklace.

According to some embodiments, light 37 (e.g. RGB LED), may be used as a variable color flashlight, by pressing a control button 35 of the holder to turn it on, and pressing again to turn the flashlight off. For example, color of the light's output may be controlled by pivoting the earpiece about the holder's fulcrum, for example, by storing instructions on a non-transitory computer readable medium that causes a controller to perform the step of control, response to determining that pivoting has occurred (e.g. by detection of connection and disconnection of the charging circuit or by proximity sensor 1007). Additionally or alternatively, light 37 (e.g. RGB LED), may also act as a programmable multicolor push notification indicator for messaging applications. The system or earpiece holder may be configured such that, through software control and network connectivity, a user's messaging application notifications are forwarded via any available wireless network to the holder (1), whereupon the light 37 may periodically cycle through a number of pulses, in the respective conventional colors associated with many messaging applications, to indicate a number of new or unread messages for each respective messaging application. Additionally, the earpiece holder may be programmed with custom-assigned colors to pulse the light 37 for notifications from any messaging application. As yet a further example, utilizing AI, text-to-voice and voice-to-text software, the device may be used for dictation to record and convert verbal communication to text for the purpose of drafting messages to any of the user's contacts. Similarly, the device may be used to convert incoming text messages and documents to spoken language for audio playback.

In some embodiments, as examples of myriad configurations for the systems functional controls, the holder's camera 1003 may be initiated to capture an image by pressing the control button 33 twice quickly, within one second. The earpiece holder's laser pointer 83 may be turned on by quickly pressing control button 33 once. The laser pointer 83 may remain on for a desirable duration of seconds and then turn off automatically. Due to the laser beam's proximity to the center of the camera's field of view, while the laser pointer 83 is turned on, it may be used as a reference center point for capturing an image with the camera, such that once the laser pointer is turned on, the user may further quickly double press the control button 33 to capture an image, whereby the laser pointer 83 is turned off prior to the image being captured, so that the laser beam will not show in the captured image. Video recording may be achieved by long holding control button 33 until an audio and/or video notification indicates that video recording has commenced and is in progress. This may include a pulsing of the light 37 (e.g. RGB LED) for the duration of video recording. As an example, the system may be configured such that pressing control button 33 again ends video recording.

In some embodiments, by means of software integration, the earpiece holder's laser pointer 83 may also be used in conjunction with input from the IMU 97 and GPS transceiver 117 to aid in way finding, according to desired headings or destination coordinates, by variably pulsing the laser pointer 83, such as a progressively higher frequency pulse as one deviates from a prescribed heading.

In some embodiments, the earpiece holder may be used to make and receive cellular phone calls as well as conduct voice-prompted internet queries and receive answers by means of the earpiece holder's communications hardware including its microphones 21, 39, speaker 31 and software integration with the holder's transceivers 117, 121 and SIM card reader 123. The holder may be network dependent on a parent network-connected device such as a smartphone, within operational range of signal for Bluetooth or WIFI connectivity with said parent device. Additionally, the earpiece holder may be provided with its own SIM card or E-SIM card, such that the earpiece holder may be connected to a network locally—via nearby network-connected wireless device such as a smartphone—or independently, such that it may connect to any available network via cellular network towers. With cellular service enabling call and data forwarding, the earpiece holder may make and receive calls, send and receive data independently so long as a cellular tower is within range. The earpiece may be used as a network connected audio extension of the holder such that all the audio and network functionality of the earpiece holder described herein may be conducted via the earpiece. The earpiece may also act as a network connected audio extension to transmit and receive audio, to and from a plurality of other wireless Bluetooth-enabled devices such as smartphones and computers, and may be switched between devices by voice prompt and command via voice auto-attendant software, which may be in the form of integrated device firmware and/or third party software.

In some embodiments, as examples of myriad configurations for voice prompt and command functionality, the holder's control button 15 may be pressed to initiate a voice command or query in natural language. The auto-attendant software may control the device's on-board functionality as well as interactions via internet. When the applicable auto-attendant software requests confirmation of a requested command as restated by the auto-attendant, control button 15 can serve as a user's affirmative response to complete the requested command, and control button 17 can serve as a user's negative response, whereupon the auto-attendant may suggest its second best guess or alternative command. In such scenarios, affirmative and negative responses may also be issued by a user's voice. Examples of such audio-based functionality include internet queries for turn-by-turn map directions, factual answers, request to convert and play back contents of any text based web page or document, record and transcribe a user's voice dictation, and so on. Additionally, a user may enable many of the device's components to be voice-activable via integrated software settings, e.g. a user might enable the flashlight to be voice-activable by saying “flashlight on” or a user's selected pre-recorded template for a voice command. After a user has finished interacting with auto-attendant software, the user may long press control button 17 at any time to disable voice-attendant software.

In some embodiments, the earpiece holder or system may have any one or any combination of the following features. As shown in the figures, the earpiece holder may be designed with a rear cover 65 which detachably attaches to the holder's main body 63 by means of corresponding aligned snap connectors (69, 71). The earpiece holder is balanced such that the anti-friction anti-wear contact patch 81 of the rear cover 65 serves as an axis of rotation when the earpiece holder is placed upon a flat surface. The holder's contact patch 81 serves as the natural point of contact with a flat surface, such that the earpiece holder may be spun freely on any flat surface, as one would with a spinning top. Additionally, by means of software and hardware integration including the IMU 97 and CPU 113 timer, the earpiece holder may count the number of revolutions per ‘spin’ and record other data associated with a spinning top. Results may be communicated to a user by auto-attendant produced voice response in a ‘spin game’ mode. These capabilities lend themselves to game play as well as study of basic mechanics and physics, for example by guessing and verifying the number of rotations and duration of a spin, players may create games beyond ‘spin the bottle’ while also testing coefficients of friction and drag by means of spinning on various surfaces, under varying conditions, modifications and so on.

In some embodiments, when the earpiece is mounted to the earpiece holder and the earpiece holder is placed on a flat surface, the earpiece holder is configured to naturally wobble and/or spin due to any physical disturbance. In such context, when a user presses on the earpiece's press point 46 to pivot and deploy the earpiece, the earpiece holder will first react to the impulse by pivoting upon its contact patch 81 until the clothes clip 45 contacts the flat surface and begins to flex until it bottoms out on the holder's rear cover 65, such that the earpiece holder now contacts the flat surface at three points including the contact patch 81 and the two points of prominence on the clothes clip 45 indicated with rubber dots 67. Thus, a momentary tripod stance is achieved while pressing on the press point 46 of the earpiece whilst mounted to the earpiece holder, facilitating removal and deployment of the earpiece from the earpiece holder in a stabilized freestanding position, on a flat surface such as a desk or table. This sequence is illustrated by progression through FIGS. 13, 14, 15.

In some embodiments, the earpiece and earpiece holder each are provided with two microphones (10, 26) and (21, 39) respectively, for the benefit of software integrated noise canceling. Additionally, three or four of these microphones may be utilized to improve noise canceling capability for either the earpiece holder or earpiece when in use.

In some embodiments, the earpiece has a capacitive touch sensor 20 mounted to a mechanical switch 30, wherein the capacitive touch sensor 20 responds to gestures such as tap, double tap, touch/hold and swipe, which may be used to control functions such as volume, mute/unmute, merge calls, switch to holder's speaker 31. The underlying mechanical switch 30 may be responsive to pressing, double pressing, which may be used to initiate and end calls, as well as to initiate and end auto-attendant software.

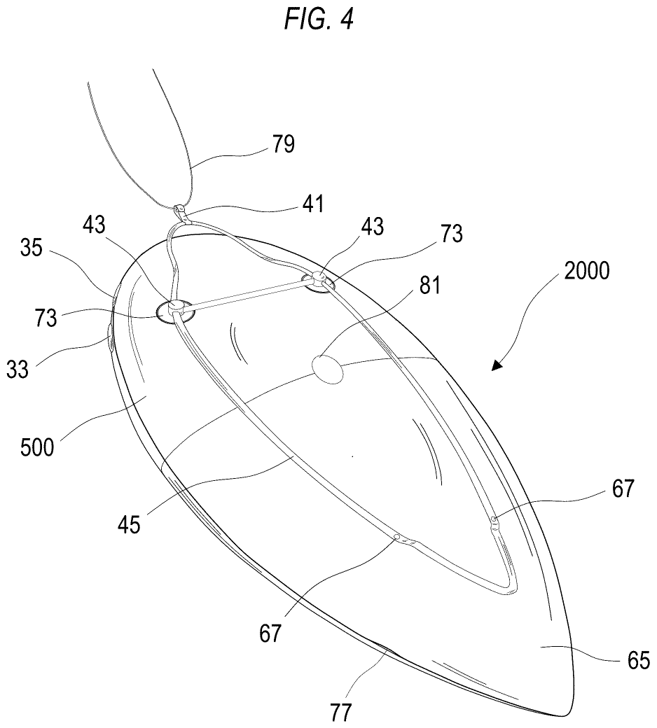

In some embodiments, as shown in FIG. 4, the earpiece holder is configured as a wearable device, and the earpiece holder can be readily and detachably attached to most any article of clothing, chain, lanyard or necklace by means of a clothes clip 45 and/or spring clasp 41. The earpiece holder may be provided with a necklace 79, the spring clasp 41 is easily adapted to a user's preferred necklace. The clothes clip 45 has two mounting pins 43 which pass through two holes in in the holder's rear cover 65 to seat in two mounting pin holes 75 in the earpiece holder's main body 63. However, in alternative configurations, the earpiece holder may be configured differently, for example, as a device other than a wearable device. For example, the earpiece holder may omit any one or any combination of the aforementioned features.

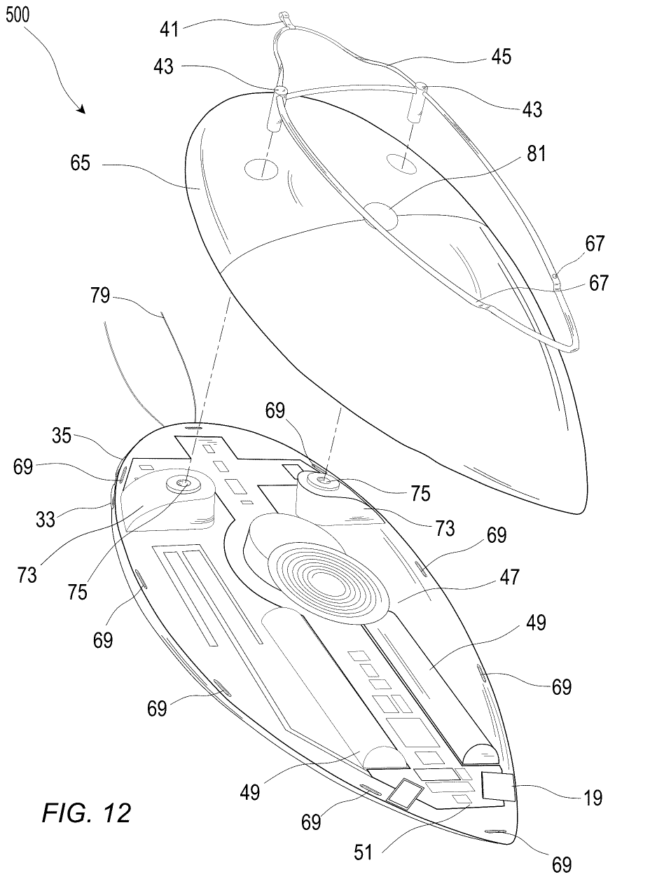

In some embodiments, as shown in the exploded view of FIG. 12, the earpiece holder's rear cover 65 mounts to the holder's main body 63 by means male and female snap connectors 69, 71 and the rear cover 65 may be removed by first removing the clothes clip 45 from the holder's main body 63 by lifting the rear cover 65 using the rear cover release notch 77. However, in alternative configurations, the earpiece holder may be configured differently. For example, the earpiece holder may omit any one or any combination of the aforementioned features.

Similarly, in some embodiments, the earpiece's top cover 40 mounts to the main body 38 by means of male and female snap connectors 42, 44, and the top cover 40 may be separated from the main body 38 by using the top cover release a notch to access the earpiece's PCB 28 or 24. However, in alternative configurations, the earpiece may be configured differently. For example, the earpiece holder may omit any one or any combination of the aforementioned features.

In some embodiments, the earpiece's speaker 2006 is housed within the neck 22, which has an annular groove about its exterior that receives an ear gel 2008 of elastomeric material having three protruding nubs 2014 which flex to provide a one size functional fit for human ears.

As further examples, the present technology contemplates each of the example embodiments (“EE”) listed below.

EE 1. A system comprising an earpiece, an earpiece holder, and a first releasable fastener,
wherein the earpiece comprises an audio transmitter and an earpiece body;
wherein the earpiece body comprises a first portion, a second portion, and a third portion;
wherein the earpiece holder comprises a housing having a fulcrum and a first earpiece body support;
wherein the fulcrum is engageable with the third portion of the earpiece body such that the earpiece body can pivot about the fulcrum from a first position to a second position and from the second position to the first position;
wherein the first earpiece body support is configured to engage the earpiece body when the earpiece body is in the first position; and
wherein the first releasable fastener is configured for releasably attaching the first portion of the earpiece body to the first earpiece body support when the earpiece body is in the first position.

EE 2. The system of EE 1, wherein the first releasable fastener comprises at least one magnet.

EE 3. The system of EE 2, wherein the at least one magnet is disposed about an interface of the first earpiece body support and the first portion.

EE 4. The system of any of EEs 1 to 3, wherein the third portion is between the first portion and the second portion.

EE 5. The system of EE 4,
a. wherein the earpiece holder further comprises a second earpiece body support configured to engage the earpiece body when the earpiece body is in the second position; and
b. wherein the fulcrum is between the first earpiece body support and the second earpiece body support.

EE 6. The system of EE 5, wherein the system further comprises a second releasable fastener configured for releasably attaching the second portion of the earpiece body to the second earpiece body support when the earpiece body is in the second position.

EE 7. The system of EE 6, wherein the second releasable fastener comprises at least one magnet.

EE 8. The system of EE 7, wherein the at least one magnet of the second releasable fastener is disposed about an interface of the second earpiece body support and the second portion.

EE 9. The system of any of EEs 1 to 8, wherein the first portion has an ear interface.

EE 10. The system of EE 9, wherein the earpiece holder further comprises a cavity for receiving the ear interface (‘ear interface cavity’) at least when the earpiece body is in the first position.

EE 11. The system of EE 10,
wherein the earpiece holder further comprises a cavity in which the fulcrum is disposed (‘fulcrum cavity’);
wherein the fulcrum cavity has a cavity wall; and
wherein the ear interface cavity is recessed in the cavity wall of the fulcrum cavity.

EE 12. The system of any of EEs 1-6, wherein the earpiece holder further comprises a cavity in which the fulcrum is disposed (‘fulcrum cavity’).

EE 13. The system of EE 11 or EE 12, wherein the fulcrum cavity is configured such that when the earpiece body is in the second position, the second portion is inside the fulcrum cavity and at least part of the first portion protrudes from the fulcrum cavity.

EE 14. The system of EE 13, wherein the fulcrum cavity is further configured such that when the earpiece body is in the first position, the at least part of the first portion does not protrude from the fulcrum cavity.

EE 15. The system of EE 14, wherein the fulcrum cavity is further configured such that when the earpiece body is in the first position, the second portion is in the fulcrum cavity and the second portion does not protrude from the fulcrum cavity.

EE 16. The system of any preceding EE, further comprising a detection circuit configured to detect a change in position of the earpiece relative to the earpiece holder and execute a function of the system responsive to said detection of the change in position.

EE 17. The system of EE 16, wherein the detection circuit comprises a proximity sensor configured to detect said change in position based on proximity of the earpiece relative to the earpiece holder.

EE 18. The system of any preceding EE,
wherein the earpiece has a battery;
wherein the earpiece holder has a power source; and
wherein the system is configured to charge the battery from the power source.

EE 19. The system of EE 18,
wherein the earpiece has a first set of conductors operably connected to the battery;
wherein the earpiece holder has a second set of conductors operably connected to the power source; and
wherein the first set of conductors and the second set of conductors are disposed in respective locations about the earpiece and the earpiece holder, respectively, such that the first set of conductors and the second set of conductors are electrically connected to each other when the earpiece body is in the first position.

EE 20. The system of EE 19,
wherein the earpiece holder further comprises a second earpiece body support disposed a distance from the fulcrum and configured to engage the earpiece body when the earpiece body is in the second position;
   c. wherein the fulcrum is between the first earpiece body support and the second earpiece body support; and
wherein the second set of conductors is disposed about the first earpiece body support and wherein the first set of conductors is disposed about the first portion of the earpiece body.

EE 21. The system of EE 18,
wherein the earpiece has a receiver coil operably connected to the battery;
wherein the earpiece holder has a sender coil operably connected to the power source; and
wherein the receiver coil and the sender coil are disposed in respective locations about the earpiece and the earpiece holder, respectively, such that the receiver coil and the sender coil are inductively coupled to each other when the earpiece body is in the first position.

EE 22. The system of EE 21,
wherein the earpiece holder further comprises a second earpiece body support disposed a distance from the fulcrum and configured to engage the earpiece body when the earpiece body is in the second position; and
   d. wherein the fulcrum is between the first earpiece body support and the second earpiece body support; and
wherein the sender coil is disposed about the first earpiece body support and the receiver coil is disposed about the first portion of the earpiece body.

EE 23. The system of any preceding EE, wherein the earpiece holder has a switch that is activatable upon the earpiece body being pivoted to the second position.

EE 24. The system of EE 23, wherein the switch is disposed about the second earpiece body support.

EE 25. The system of any preceding EE,
wherein the earpiece holder has a base on an opposing side of the earpiece holder, relative to the fulcrum;
wherein the base has:
at least one foot; and
at least one balancing portion on which the earpiece holder can balance when the earpiece holder is placed on a horizontal surface;
wherein the at least one balancing portion and the at least one foot are each disposed about the earpiece holder such that, when the earpiece holder is balanced on the horizontal surface by the at least one balancing portion, the at least one balancing portion is lower than the at least one foot and when a downward force is applied laterally of the at least one balancing portion to rock the earpiece holder about the at least one balancing portion, the at least one foot is rocked in a downward direction to engage the horizontal surface; and
wherein the at least one foot is configured to prevent further rocking in the downward direction when engaged with the horizontal surface.

EE 26. The system of EE 25,
wherein the base has a convex arc;
wherein the at least one balancing portion is a portion of the convex arc; and
wherein the at least one foot protrudes from the convex arc.

EE 27. The system of any preceding EE,
wherein the earpiece holder has a central portion, a first end, and a second end;
wherein the central portion is between the first end and the second end;
wherein the earpiece holder tapers from the central portion to the first end in one or both of lateral thickness and longitudinal thickness;
wherein the earpiece holder tapers from the central portion to the second end in one or both of lateral thickness and longitudinal thickness; and
wherein the taper from the central portion to the first end in one or both of lateral thickness and longitudinal thickness is more gradual than the taper from the central portion to the second end in one or both of lateral thickness and longitudinal thickness.

EE 28. The system of EE 27,
e. wherein the taper from the central portion to the first end in lateral thickness is longitudinally symmetrical;
f. wherein the taper from the central portion to the second end in lateral thickness is longitudinally symmetrical;
   wherein the taper from the central portion to the first end in longitudinal thickness is laterally symmetrical; and
g. wherein the taper from the central portion to the second end in longitudinal thickness is laterally symmetrical.

EE 29. The system of EE 27 or 28, wherein any one or any combination of the tapers is an arcuate taper.

EE 30. The system of EE 29, wherein the earpiece holder has an almond shape.

EE 31. The system of any preceding EE,
wherein the earpiece body has a central portion, a first end, and a second end;
wherein the central portion of the earpiece body is between the first end of the earpiece body and the second end of the earpiece body;
wherein the earpiece body tapers from the central portion of the earpiece body to the first end of the earpiece body in one or both of lateral thickness and longitudinal thickness;
wherein the earpiece body tapers from the central portion of the earpiece body to the second end of the earpiece body in one or both of lateral thickness and longitudinal thickness; and
wherein the taper from the central portion of the earpiece body to the first end of the earpiece body in one or both of lateral thickness and longitudinal thickness is more gradual than the taper from the central portion of the earpiece body to the second end of the earpiece body in one or both of lateral thickness and longitudinal thickness.

EE 32. The system of EE 31,
h. wherein the taper from the central portion of the earpiece body to the first end in lateral thickness is longitudinally symmetrical;
i. wherein the taper from the central portion of the earpiece body to the second end of the earpiece body in lateral thickness is longitudinally symmetrical;
   wherein the taper from the central portion of the earpiece body to the first end in longitudinal thickness is laterally symmetrical; and
j. wherein the taper from the central portion of the earpiece body to the second end of the earpiece body in longitudinal thickness is laterally symmetrical.

EE 33. The system of EE 31 or EE 32, wherein any one or any combination of the tapers of the earpiece body is an arcuate taper.

EE 34. The system of EE 33, wherein the earpiece body has an almond shape.

EE 35. The system of any preceding EE, wherein the earpiece holder comprises a magnet comprising a first portion and a second portion, wherein the first portion comprises the fulcrum and the second portion comprises a coupler of the first releasable fastener.

EE 36. The system of EE 35, wherein the fulcrum is an edge of the magnet of the earpiece holder.

EE 37. An earpiece holder for storing an earpiece having an earpiece body comprising a first portion, a second portion, and a third portion, the earpiece holder comprising a housing and a coupler of a first releasable fastener,
wherein the housing comprises a fulcrum and a first earpiece body support;
   k. wherein the fulcrum is engageable with the third portion such that the earpiece body can pivot about the fulcrum to pivot the earpiece body from a first position to a second position and from the second position to the first position; and
wherein the first earpiece body support is disposed a distance from the fulcrum and configured to engage the earpiece body when the earpiece body is in the first position; and
wherein the coupler of a first releasable fastener is configured for releasably attaching the first portion of the earpiece body to the first earpiece body support when the earpiece body is in the first position.

EE 38. An earpiece configured for storage by an earpiece holder having a fulcrum and a first earpiece body support, the earpiece comprising an audio transmitter, an earpiece body, and a coupler of a first releasable fastener,
l. wherein the earpiece body comprises a first portion, a second portion, and a third portion, the third portion being configured to engage the fulcrum such that the earpiece body can pivot about the fulcrum from a first position to a second position and from the second position to the first position; and
m. wherein the coupler of a first releasable fastener is configured for releasably attaching the first portion of the earpiece body to a first earpiece body support of the earpiece holder when the earpiece body is in the first position.

EE 39. A method of using the system of EE 1, the method comprising:
providing the system;
pivoting the third portion of the earpiece body about the fulcrum to move the earpiece body from the second position to the first position;
attaching the first portion of the earpiece body to the first earpiece body support when the earpiece body is in the first position;
detaching the first portion of the earpiece from the first earpiece body support; and
pivoting the third portion of the earpiece body about the fulcrum to move the earpiece body from the first position to the second position.

EE 40. The method 38, further comprising causing a controller of the earpiece holder to perform control of at least one electronic component of the earpiece holder responsive to said pivoting the third portion of the earpiece body about the fulcrum to move the earpiece body from the second position to the first position or said pivoting the third portion of the earpiece body about the fulcrum to move the earpiece body from the first position to the second position.

EE 41. A method comprising:
providing a system comprising an earpiece and an earpiece holder; wherein the earpiece comprises an audio transmitter and an earpiece body, wherein the earpiece body comprises a first portion, a second portion, and a third portion; wherein the earpiece holder comprises a housing having a fulcrum; wherein the fulcrum is engageable with the third portion of the earpiece body such that the earpiece body can pivot about the fulcrum from a first position to a second position and from the second position to the first position;
pivoting the third portion of the earpiece body about the fulcrum to move the earpiece body from the second position to the first position; and
pivoting the third portion of the earpiece body about the fulcrum to move the earpiece body from the first position to the second position.

EE 42. The method of EE 41, further comprising retaining the earpiece body in the first position for a period of time and/or retaining the earpiece body in the second position for a period of time.

EE 43. The method of EE 42, wherein the step of retaining the earpiece body in the first position for a period of time comprises releasably attaching the earpiece body to the earpiece holder by a first releasable fastener and/or wherein the step of retaining the earpiece body in the second position for a period of time comprises releasably attaching the earpiece body to the earpiece holder by a second releasable fastener.

EE 44. The method of EE 43, wherein the first releasable fastener comprises a magnet and/or wherein the second fastener comprises a magnet.

EE45 The method any of EE 41-EE 44, further comprising causing a controller of the earpiece holder to perform control of at least one electronic component of the earpiece holder responsive to at least one of said pivoting steps.

What is claimed is:

1. A system comprising an earpiece, an earpiece holder, and a first releasable fastener,
wherein the earpiece comprises an audio transmitter and an earpiece body;
wherein the earpiece body comprises a first portion, a second portion, and a third portion;
wherein the earpiece holder comprises a housing having a fulcrum and a first earpiece body support;
wherein the fulcrum is engageable with the third portion of the earpiece body such that the earpiece body can pivot about the fulcrum from a first position to a second position and from the second position to the first position;
wherein the first earpiece body support is configured to engage the earpiece body when the earpiece body is in the first position; and
wherein the first releasable fastener is configured for releasably attaching the first portion of the earpiece body to the first earpiece body support when the earpiece body is in the first position.

2. The system of claim 1, wherein the first releasable fastener comprises at least one magnet.

3. The system of claim 2, wherein the at least one magnet is disposed about an interface of the first earpiece body support and the first portion.

4. The system of claim 1, wherein the third portion is between the first portion and the second portion.

5. The system of claim 4,
wherein the earpiece holder further comprises a second earpiece body support configured to engage the earpiece body when the earpiece body is in the second position; and
wherein the fulcrum is between the first earpiece body support and the second earpiece body support.

6. The system of claim 5, wherein the system further comprises a second releasable fastener configured for releasably attaching the second portion of the earpiece body to the second earpiece body support when the earpiece body is in the second position.

7. The system of claim 6, wherein the second releasable fastener comprises at least one magnet.

8. The system of claim 7, wherein the at least one magnet of the second releasable fastener is disposed about an interface of the second earpiece body support and the second portion.

9. The system of claim 1, wherein the first portion has an ear interface.

10. The system of claim 9, wherein the earpiece holder further comprises a cavity for receiving the ear interface (‘ear interface cavity’) at least when the earpiece body is in the first position.

11. The system of claim 10,
wherein the earpiece holder further comprises a cavity in which the fulcrum is disposed (‘fulcrum cavity’);
wherein the fulcrum cavity has a cavity wall; and
wherein the ear interface cavity is recessed in the cavity wall of the fulcrum cavity.

12. The system of claim 1, wherein the earpiece holder further comprises a cavity in which the fulcrum is disposed (‘fulcrum cavity’).

13. The system of claim 12, wherein the fulcrum cavity is configured such that when the earpiece body is in the second position, the second portion is inside the fulcrum cavity and another portion of the earpiece body protrudes from the fulcrum cavity.

14. The system of claim 13, wherein the fulcrum cavity is further configured such that when the earpiece body is in the first position, the another portion does not protrude from the fulcrum cavity.

15. The system of claim 1,
wherein the earpiece holder has a base on an opposing side of the earpiece holder, relative to the fulcrum;
wherein the base has:
at least one foot; and
at least one balancing portion on which the earpiece holder can balance when the earpiece holder is placed on a horizontal surface;
wherein the at least one balancing portion and the at least one foot are each disposed about the earpiece holder such that, when the earpiece holder is balanced on the horizontal surface by the at least one balancing portion, the at least one balancing portion is lower than the at least one foot and when a downward force is applied laterally of the at least one balancing portion to rock the earpiece holder about the at least one balancing portion, the at least one foot is rocked in a downward direction to engage the horizontal surface; and
wherein the at least one foot is configured to prevent further rocking in the downward direction when engaged with the horizontal surface.

16. The system of claim 1,
wherein the earpiece holder has a central portion, a first end, and a second end;
wherein the central portion is between the first end and the second end;
wherein the earpiece holder tapers from the central portion to the first end in one or both of lateral thickness and longitudinal thickness;
wherein the earpiece holder tapers from the central portion to the second end in one or both of lateral thickness and longitudinal thickness; and
wherein the taper from the central portion to the first end in one or both of lateral thickness and longitudinal thickness is more gradual than the taper from the central portion to the second end in one or both of lateral thickness and longitudinal thickness.

17. The system of claim 1, wherein the earpiece holder comprises a magnet comprising a first portion and a second portion, wherein the first portion comprises the fulcrum and the second portion comprises a coupler of the first releasable fastener.

18. An earpiece holder for storing an earpiece having an earpiece body comprising a first portion, a second portion, and a third portion, the earpiece holder comprising a housing and a coupler of a first releasable fastener,
wherein the housing comprises a fulcrum and a first earpiece body support;
wherein the fulcrum is engageable with the third portion such that the earpiece body can pivot about the fulcrum to pivot the earpiece body from a first position to a second position and from the second position to the first position; and
wherein the first earpiece body support is disposed a distance from the fulcrum and configured to engage the earpiece body when the earpiece body is in the first position; and
wherein the coupler of the first releasable fastener is configured for releasably attaching the first portion of the earpiece body to the first earpiece body support when the earpiece body is in the first position.

19. An earpiece configured for storage by an earpiece holder having a fulcrum and a first earpiece body support, the earpiece comprising an audio transmitter, an earpiece body, and a coupler of a first releasable fastener,
wherein the earpiece body comprises a first portion, a second portion, and a third portion, the third portion being configured to engage the fulcrum such that the earpiece body can pivot about the fulcrum from a first position to a second position and from the second position to the first position; and
wherein the coupler of the first releasable fastener is configured for releasably attaching the first portion of the earpiece body to a first earpiece body support of the earpiece holder when the earpiece body is in the first position.

20. A method of using the system of claim 1, the method comprising:
providing the system;
pivoting the third portion of the earpiece body about the fulcrum to move the earpiece body from the second position to the first position;
attaching the first portion of the earpiece body to the first earpiece body support when the earpiece body is in the first position;
detaching the first portion of the earpiece from the first earpiece body support; and
pivoting the third portion of the earpiece body about the fulcrum to move the earpiece body from the first position to the second position.
